(19) United States
(12) Patent Application Publication
(10) Pub. No.: US 2014/0252371 A1
(43) Pub. Date: Sep. 11, 2014

(54) HETEROJUNCTION TRANSISTOR AND METHOD OF FABRICATING THE SAME

(71) Applicant: Seoul Semiconductor Co., Ltd., Ansan-si (KR)

(72) Inventors: June Sik KWAK, Ansan-si (KR); Yu Dae HAN, Ansan-si (KR); Kwan Hyun LEE, Ansan-si (KR); Motonobu TAKEYA, Ansan-si (KR); Young Do JONG, Ansan-si (KR)

(73) Assignee: Seoul Semiconductor Co., Ltd., Ansan-si (KR)

(21) Appl. No.: 14/199,254

(22) Filed: Mar. 6, 2014

(30) Foreign Application Priority Data
Mar. 8, 2013 (KR) 10-2013-0025204
Mar. 11, 2013 (KR) 10-2013-0025541

(51) Int. Cl. H01L 29/778; H01L 29/20; H01L 29/66

(52) U.S. Cl. CPC H01L 29/7787; H01L 29/66431; H01L 29/2003
USPC 257/76; 438/172; 257/194

(57) ABSTRACT

Exemplary embodiments of the present invention disclose a heterojunction transistor having a normally off characteristic using a gate recess structure and a method of fabricating the same. The heterojunction transistor may include a substrate, a channel layer disposed on the substrate and made of a first nitride-based semiconductor having a first energy bandgap, a first barrier layer disposed on the channel layer and made of a second nitride-based semiconductor having a second energy bandgap different from the first energy bandgap, a gate electrode disposed in a gate control region of the first barrier layer, and a second barrier layer disposed in gate non-control regions of the first barrier layer and separated from the first barrier layer.

### CROSS-REFERENCE TO RELATED APPLICATIONS

This application claims priority from and the benefit of Korean Patent Application Nos. 10-2013-0025204 and 10-2013-0025541, filed on Mar. 8, 2013, and Mar. 11, 2013, respectively, which are incorporated herein by reference for all purposes as if fully set forth herein.

### BACKGROUND

1. Field

Exemplary embodiments of the present disclosure describe an article comprising a heterojunction transistor and a method of fabricating the same, and more particularly, a heterojunction transistor having a gate recess structure with a normally off characteristic and a method of fabricating the same.

2. Discussion of the Background

With the recent development of information communication technology, there is a need for a transistor having a high-speed switching operation suitable for ultra high-speed and high-capacity signal transmission and a high voltage-resistant transistor suitable for a high-voltage environment, such as a hybrid vehicle, in various fields. However, conventional silicon-based transistors or GaAs-based transistors may have difficulties in meeting these needs due to the limits of the materials.

A nitride-based transistor, in particular a GaN-based transistor, may be suitable for ultra high-speed signal processing because it enables a high-speed switching operation as compared with a conventional silicon transistor and may be suitable for a high-voltage environment due to a high voltage-resistant characteristic of the material. In particular, a nitride-based transistor, for example, a High Electron Mobility Transistor (HEMT) or a Heterostructure FET (HFET) using a heterojunction structure may be suitable for high-speed signal transmission due to high electron mobility because an electric current flows using Two-Dimensional Electron Gas (2DEG) generated at the interface between heterogeneous materials.

A method of fabricating a conventional heterojunction transistor having a gate recess structure is illustrated in FIG. 1. As shown in FIGS. 1(a) to 1(d), the conventional heterojunction transistor 100 is a normally off transistor using a gate recess, and it includes a buffer layer 120, a channel layer 130, a barrier layer 140, contact pad layers 165 and 175, a gate electrode 150, a source electrode 160, and a drain electrode 170 grown over a substrate 110. The channel layer 130 and the barrier layer 140 are made of semiconductor materials having different energy bandgaps, thus forming an induction channel 2DEG.

The heterojunction transistor 100 is fabricated to have a normally off characteristic by forming a gate recess region by partially etching the barrier layer 140, forming the gate electrode 150 in the gate recess region, and forming a discontinuous region of 2DEG in a channel of 2DEG under the gate electrode 150. That is, in the conventional heterojunction transistor 100, part of the barrier layer 140 is etched in order to form the gate recess structure. If the thickness T of the barrier layer 140 under the gate electrode 150 is too small, a discontinuous region of 2DEG may be formed in a turn-off state in which a bias has not been applied to the gate electrode because piezoelectric polarization becomes weak due to the barrier layer 140 under the gate electrode 150.

In a method of fabricating the conventional heterojunction transistor 100, in order to implement a normally off characteristic, the barrier layer 140 under the gate electrode 150 may be removed so that the barrier layer 140 has a thickness of several nanometers. It may be difficult to uniformly control the thickness of the barrier layer under the gate recess to a size of several nanometers in an etch process, however, because a heterogeneous material junction surface may not have a uniform thickness. Furthermore, electron mobility may be reduced due to etch damage occurring in the barrier layer 140 when performing the etch process.

A conventional heterojunction transistor having a gate recess structure is shown in FIG. 2. As shown in FIG. 2, the conventional heterojunction transistor includes a substrate 110, a channel layer 130, a barrier layer 140, a P type semiconductor layer 200, a gate electrode 150, a source electrode 160, and a drain electrode 170. Here, a discontinuous region is formed in a 2DEG channel formed at the interface between the channel layer 130 and the barrier layer 140 due to the P type semiconductor layer 200 formed under the gate electrode 150.

The aforementioned conventional heterojunction transistor, however, may not have a conduction band level sufficiently raised due to the limit of a hole doping concentration using magnesium (Mg) in the P type semiconductor layer 200, and thus reliability may be decreased in forming a discontinuous region in the channel of 2DEG.

Furthermore, if the P type semiconductor layer 200 is grown to a thickness of about 100 nm by doping magnesium (Mg) of a high concentration or if the barrier layer 140 is grown to a thickness of about 10 nm or more using a composition of Al_{0.25}Ga_{0.75}N, the conventional heterojunction transistor 100 may have a normally on characteristic instead of a normally off characteristic.

Moreover, after growing the P type semiconductor layer 200, the remaining parts other than a part where the gate electrode 150 will be formed need to be etched in order to form the gate electrode 150. In such a case, positive charges may accumulate on a surface of the barrier layer due to plasma damage generating in the etch process, and a current collapse phenomenon in which a 2DEG characteristic is deteriorated due to the accumulated positive charges may be accelerated.

As described above, the conventional gate recess transistor structure having a normally off characteristic may have low device reliability because the transistor is fabricated through etching of several tens of nanometers and low yield due to characteristic deviation in each transistor device upon mass production. Furthermore, a current collapse phenomenon in which a 2DEG characteristic is deteriorated due to plasma damage may be accelerated.

### SUMMARY OF THE INVENTION

Exemplary embodiments of the present invention provide a heterojunction transistor and a method of fabricating the same, which are capable of controlling the thickness of a barrier layer under a gate through a regrowth scheme without an etch process.

Exemplary embodiments of the present invention also provide a heterojunction transistor and a method of fabricating the same, which are capable of controlling an aluminum (Al) composition ratio in a control region and the thickness of a barrier layer through an epitaxial process when growing a primary barrier layer.

Exemplary embodiments of the present invention also provide a heterojunction transistor and a method of fabricating the same, which are capable of controlling an Al composition ratio in gate non-control regions and the thickness of a barrier layer through a plurality of growth processes.

Exemplary embodiments of the present invention also provide a heterojunction transistor and a method of fabricating the same, which are capable of simplifying a process of fabricating a transistor using an insulating film mask formed in a gate control region as a gate insulating film when growing a secondary barrier layer.

Exemplary embodiments of the present invention also provide a heterojunction transistor and a method of fabricating the same, which are capable of providing a high drain current characteristic as compared with an existing Metal Insulator Semiconductor Heterojunction Field Effect Transistor (MIS-HFET) structure.

Exemplary embodiments of the present invention also provide a heterojunction transistor and a method of fabricating the same, which are capable of providing an excellent interfacial characteristic between a gate and a channel layer.

Exemplary embodiments of the present invention also provide a heterojunction transistor and a method of fabricating the same, which are capable of improving threshold voltage using a combination of a P type semiconductor layer and an insulating masking layer.

Other objects and advantages of the present invention can be understood by the following description, and become apparent with reference to the exemplary embodiments of the present invention. Also, it is obvious to those skilled in the art to which the present invention pertains that the objects and advantages of the present invention can be realized by the means as claimed and combinations thereof.

In accordance with an exemplary embodiment of the present invention, a method of fabricating a heterojunction transistor includes a first step of preparing a substrate; a second step of forming a channel layer, made of a first nitride-based semiconductor having a first energy bandgap, over the substrate; a third step of forming a first barrier layer, made of a second nitride-based semiconductor having a second energy bandgap different from the first energy bandgap, over the channel layer; a fourth step of selectively forming an insulating masking layer in a gate control region on the first barrier layer; a fifth step of forming a second barrier layer, made of a third nitride-based semiconductor having a third energy bandgap different from the first energy bandgap, over the first barrier layer in the thickness identical with or lower than the thickness of the insulating masking layer; and a sixth step of removing the insulating masking layer and forming a gate electrode over the first barrier layer exposed to the gate control region. Here, the method may further include a seventh step of forming a source electrode and a drain electrode over the second barrier layer after the sixth step.

In the method of fabricating a heterojunction transistor in accordance with an exemplary embodiment of the present invention, the third step may include forming the first barrier layer in the thickness in which a Two-Dimensional Electron Gas (2DEG) channel is not formed through the junction of the channel layer and the first barrier layer in the state in which a bias has not been applied to the gate electrode, and the fifth step may include forming the second barrier layer in the thickness in which the 2DEG channel is formed through the junction of the first barrier layer, the second barrier layer, and the channel layer in the state in which a bias has not been applied to the gate electrode.

In the method of fabricating a heterojunction transistor in accordance with an exemplary embodiment of the present invention, the third step may include forming the first barrier layer made of the second nitride-based semiconductor having the second energy bandgap greater than the first energy bandgap, and the fifth step may include forming the second barrier layer made of the third nitride-based semiconductor having the third energy bandgap greater than the first energy bandgap.

In the method of fabricating a heterojunction transistor in accordance with a an exemplary embodiment of the present invention, the fifth step may include forming the second barrier layer in the thickness greater than the thickness of the first barrier layer, and the second barrier layer may be made of the third nitride-based semiconductor having the third energy bandgap identical with the second energy bandgap.

In the method of fabricating a heterojunction transistor in accordance with an exemplary embodiment of the present invention, the fifth step may include forming the second barrier layer using the third nitride-based semiconductor having the third energy bandgap greater than the second energy bandgap.

In the method of fabricating a heterojunction transistor in accordance with an exemplary embodiment of the present invention, the first nitride-based semiconductor may be made of GaN materials, and the second nitride-based semiconductor and the third nitride-based semiconductor may be made of AlₓGa₁₋ₓN materials. Here, the third nitride-based semiconductor may have a higher Al composition ratio higher than the second nitride-based semiconductor.

In the method of fabricating a heterojunction transistor in accordance with an exemplary embodiment of the present invention, the third step may include forming the first barrier layer made of the second nitride-based semiconductor having an Al composition ratio of about 5% to about 25% and formed in the thickness of about 3 nm or more to about 15 nm or less. The fifth step may include forming the second barrier layer made of the third nitride-based semiconductor having an Al composition ratio of about 15% to about 100% and formed in the thickness of about 5 nm to about 30 nm.

In the method of fabricating a heterojunction transistor in accordance with an exemplary embodiment of the present invention, the fourth step may include forming the insulating masking layer in the thickness of about 10 nm to about 500 nm.

In the method of fabricating a heterojunction transistor in accordance with an exemplary embodiment of the present invention, the second step may include a first sub-step of forming a buffer layer over the substrate, a second sub-step of forming a high-temperature undoped GaN layer over the buffer layer, a third sub-step of forming a compensation layer, made of GaN into which electron-trapping impurities have been doped, over the high-temperature undoped GaN layer, and a fourth sub-step of forming a channel layer, made of high-quality GaN materials having defect density of 10⁸/cm² or less, over the compensation layer.

In the method of fabricating a heterojunction transistor in accordance with an exemplary embodiment of the present invention, the first step may include preparing a sapphire substrate as the substrate, the first sub-step may include forming the buffer layer using a single AlGaN layer or a plurality of AlGaN layers having different Al composition ratios, the second sub-step may include forming the high-temperature undoped GaN layer in the thickness of about 0.01 μm to about 1 μm, the third sub-step may include forming the compensation layer into which iron (Fe) or carbon (C) having a concentration of 1E18˜1E19/cm³ has been doped as electron-trapping impurities in the thickness of about 0.01 μm to about 5 μm, and the fourth sub-step may include forming the channel layer in the thickness of about 10 nm to about 100 nm.

In the method of fabricating a heterojunction transistor in accordance with an exemplary embodiment of the present invention, the fourth step may include a fifth sub-step of forming an insulating layer over the first barrier layer, a sixth sub-step of forming a patterned photoresist layer on the insulating layer, a seventh sub-step of removing part of the insulating layer placed in the gate non-control region other than the gate control region, and an eighth sub-step of forming the insulating masking layer by removing the photoresist layer.

In accordance with an exemplary embodiment of the present invention, a method of fabricating a heterojunction transistor includes a first step of preparing a substrate; a second step of forming a channel layer, made of a first nitride-based semiconductor having a first energy bandgap, over the substrate; a third step of forming a first barrier layer, made of a second nitride-based semiconductor having a second energy bandgap different from the first energy bandgap, over the channel layer; a fourth step of selectively forming an insulating masking layer in a gate control region on the first barrier layer; a fifth step of forming a second barrier layer, made of a third nitride-based semiconductor having a third energy bandgap different from the first energy bandgap, over the first barrier layer in the thickness identical with or lower than the thickness of the insulating masking layer; and a sixth step of forming a gate electrode over the insulating masking layer. Here, the method may further include a seventh step of forming a source electrode and a drain electrode on the second barrier layer after the sixth step.

In the method of fabricating a heterojunction transistor in accordance with an exemplary embodiment of the present invention, the sixth step may include forming the gate electrode over the insulating masking layer that remains after removing part of the insulating masking layer.

In the method of fabricating a heterojunction transistor in accordance with an exemplary embodiment of the present invention, the third step may include forming the first barrier layer in the thickness in which a 2DEG channel is not formed through the junction of the channel layer and the first barrier layer in the state in which a bias has not been applied to the gate electrode, and the fifth step may include forming the second barrier layer in the thickness in which the 2DEG channel is formed through the junction of the first barrier layer, the second barrier layer, and the channel layer in the state in which a bias has not been applied to the gate electrode.

In the method of fabricating a heterojunction transistor in accordance with an exemplary embodiment of the present invention, the third step may include forming the first barrier layer made of the second nitride-based semiconductor having the second energy bandgap greater than the first energy bandgap, and the fifth step may include forming the second barrier layer made of the third nitride-based semiconductor having the third energy bandgap greater than the first energy bandgap.

In the method of fabricating a heterojunction transistor in accordance with an exemplary embodiment of the present invention, the fifth step may include forming the second barrier layer in the thickness greater than the thickness of the first barrier layer, and the second barrier layer may be made of the third nitride-based semiconductor having the third energy bandgap identical with the second energy bandgap.

In the method of fabricating a heterojunction transistor in accordance with an exemplary embodiment of the present invention, the fifth step may include forming the second barrier layer using the third nitride-based semiconductor having the third energy bandgap greater than the second energy bandgap.

In the method of fabricating a heterojunction transistor in accordance with an exemplary embodiment of the present invention, the first nitride-based semiconductor may be made of GaN materials, and the second nitride-based semiconductor and the third nitride-based semiconductor may be made of AlₓGa₁₋ₓN materials. Here, the third nitride-based semiconductor may have a higher Al composition ratio higher than the second nitride-based semiconductor.

In the method of fabricating a heterojunction transistor in accordance with an exemplary embodiment of the present invention, the third step may include forming the first barrier layer made of the second nitride-based semiconductor having an Al composition ratio of about 5% to about 25% and formed in the thickness of about 3 nm to about 15 nm, and the fifth step may include forming the second barrier layer made of the third nitride-based semiconductor having an Al composition ratio of about 15% to about 100% and formed in the thickness of about 5 nm to about 30 nm.

In the method of fabricating a heterojunction transistor in accordance with an exemplary embodiment of the present invention, the fourth step may include forming the insulating masking layer in the thickness of about 10 nm to about 500 nm.

In accordance with yet an exemplary embodiment of the present invention, a heterojunction transistor includes a substrate; a channel layer formed over the substrate and made of a first nitride-based semiconductor having a first energy bandgap; a first barrier layer formed over the channel layer and made of a second nitride-based semiconductor having a second energy bandgap different from the first energy bandgap; a gate electrode formed in a gate control region of the first barrier layer; and a second barrier layer formed in the gate non-control regions of the first barrier layer separately from the first barrier layer. Here, a source electrode and a drain electrode may be provided on the second barrier layer.

In the heterojunction transistor in accordance with an exemplary embodiment of the present invention, the gate electrode may be formed in the gate control region of the first barrier layer with the insulating masking layer interposed between the gate electrode and the first barrier layer.

In the heterojunction transistor in accordance with an exemplary embodiment of the present invention, the first barrier layer or the second barrier layer may be doped with n type impurities.

In the heterojunction transistor in accordance with an exemplary embodiment of the present invention, the first barrier layer may be formed in the thickness in which a 2DEG channel is not formed through the junction of the channel layer and the first barrier layer in the state in which a bias has not been applied to the gate electrode; and the second barrier layer may be formed in the thickness in which the 2DEG channel is formed through the junction of the first barrier layer, the second barrier layer, and the channel layer in the state in which a bias has not been applied to the gate electrode.

In the heterojunction transistor in accordance with an exemplary embodiment of the present invention, the first barrier layer may be made of the second nitride-based semiconductor having the second energy bandgap greater than the first energy bandgap, and the second barrier layer may be made of the third nitride-based semiconductor having the third energy bandgap greater than the first energy bandgap.

In the heterojunction transistor in accordance with an exemplary embodiment of the present invention, the second barrier layer may be made of the third nitride-based semiconductor having the third energy bandgap identical with the second energy bandgap and may be formed in the thickness greater than the first barrier layer.

In the heterojunction transistor in accordance with an exemplary embodiment of the present invention, the second barrier layer may be made of the third nitride-based semiconductor having the third energy bandgap greater than the second energy bandgap.

In the heterojunction transistor in accordance with an exemplary embodiment of the present invention, the first nitride-based semiconductor may be made of GaN materials, and the second nitride-based semiconductor and the third nitride-based semiconductor may be made of AlₓGa₁₋ₓN materials. Here, the third nitride-based semiconductor may have an Al composition ratio higher than the second nitride-based semiconductor.

In the heterojunction transistor in accordance with an exemplary embodiment of the present invention, the first barrier layer may be made of the second nitride-based semiconductor having an Al composition ratio of about 5% to about 25% and may be formed in the thickness of about 3 nm to about 15 nm, and the second barrier layer may be made of the third nitride-based semiconductor having an Al composition ratio of about 15% to about 100% and formed in the thickness of about 5 nm to about 30 nm.

In the heterojunction transistor in accordance with an exemplary embodiment of the present invention, the insulating masking layer may have a thickness of about 10 nm to about 500 nm.

A heterojunction transistor in accordance with an exemplary embodiment of the present invention may further include a buffer layer formed over a substrate, a high-temperature undoped GaN layer formed over the buffer layer, and a compensation layer made of GaN into which electron-trapping impurities have been doped over the high-temperature undoped GaN layer. Here, the channel layer may be formed over the compensation layer and made of high-quality GaN materials having defect density of 5E8/cm³ or less.

In the heterojunction transistor in accordance with an exemplary embodiment of the present invention, the substrate may be a sapphire substrate, the buffer layer may be formed of a single AlGaN layer or a plurality of AlGaN layers having different Al composition ratios, the high-temperature undoped GaN layer may have a thickness of about 0.01 μm to about 1 μm, the compensation layer may be doped with iron (Fe) or carbon (C) having a concentration of 5E17˜1E19/cm³ as electron-trapping impurities and formed in the thickness of about 0.01 μm to about 5 μm, and the channel layer may have a thickness of about 10 nm to about 100 nm.

In accordance with an exemplary embodiment of the present invention, a method of fabricating a heterojunction transistor includes a first step of preparing a substrate; a second step of forming a channel layer, made of a first nitride-based semiconductor having a first energy bandgap, over the substrate; a third step of forming a first barrier layer, made of a second nitride-based semiconductor having a second energy bandgap different from the first energy bandgap, over the channel layer; a fourth step of forming a P type semiconductor layer in a gate control region on the first barrier layer; a fifth step of forming a second barrier layer, made of a third nitride-based semiconductor having a third energy bandgap different from the first energy bandgap, over the first barrier layer in the thickness identical with or lower than the thickness of the P type semiconductor layer; and a sixth step of forming a gate electrode over the P type semiconductor layer.

In the method of fabricating a heterojunction transistor in accordance with a an exemplary embodiment of the present invention, the third step may include forming the first barrier layer in the thickness in which a 2DEG channel is not formed through the junction of the channel layer and the first barrier layer in the state in which a bias has not been applied to the gate electrode; and the fifth step may include forming the second barrier layer in the thickness in which the 2DEG channel is formed through the junction of the first barrier layer, the second barrier layer, and the channel layer in the state in which a bias has not been applied to the gate electrode.

In the method of fabricating a heterojunction transistor in accordance with an exemplary embodiment of the present invention, the third step may include forming the first barrier layer made of the second nitride-based semiconductor having the second energy bandgap greater than the first energy bandgap, and the fifth step may include forming the second barrier layer made of the third nitride-based semiconductor having the third energy bandgap greater than the first energy bandgap.

In the method of fabricating a heterojunction transistor in accordance with an exemplary embodiment of the present invention, the fifth step may include forming the second barrier layer in the thickness greater than the thickness of the first barrier layer. Here, the second barrier layer may be made of the third nitride-based semiconductor having the third energy bandgap identical with the second energy bandgap.

In the method of fabricating a heterojunction transistor in accordance with an exemplary embodiment of the present invention, the fifth step may include forming the second barrier layer using the third nitride-based semiconductor having the third energy bandgap greater than the second energy bandgap.

In the method of fabricating a heterojunction transistor in accordance with an exemplary embodiment of the present invention, the first nitride-based semiconductor may be made of GaN materials, and the second nitride-based semiconductor and the third nitride-based semiconductor may be made of AlₓGa₁₋ₓN materials. Here, the third nitride-based semiconductor may have an Al composition ratio higher than the second nitride-based semiconductor.

In the method of fabricating a heterojunction transistor in accordance with an exemplary embodiment of the present invention, the third step may include forming the first barrier layer made of the second nitride-based semiconductor having an Al composition ratio of about 5% to about 25% and formed in the thickness of about 3 nm to about 15 nm, and the fifth step may include forming the second barrier layer made of the third nitride-based semiconductor having an Al composition ratio of about 15% to about 100% and formed in the thickness of about 5 nm to about 30 nm.

In the method of fabricating a heterojunction transistor in accordance with a an exemplary embodiment of the present invention, the fourth step may include forming the P type semiconductor layer in the thickness of about 10 nm to about 80 nm.

In the method of fabricating a heterojunction transistor in accordance with an exemplary embodiment of the present invention, the second step may include a second-1 step of forming a buffer layer over the substrate, a second-2 step of forming a high-temperature undoped GaN layer over the buffer layer, a second-3 step of forming a compensation layer, made of GaN materials into which electron-trapping impurities have been doped, over the high-temperature undoped GaN layer, and a second-4 step of forming a channel layer, made of high-quality GaN materials having defect density of 5E8/cm² or less, over the compensation layer.

In the method of fabricating a heterojunction transistor in accordance with an exemplary embodiment of the present invention, the first step may include preparing a sapphire substrate as the substrate, the second-1 step may include forming the buffer layer using a single AlGaN layer or a plurality of AlGaN layers having different Al composition ratios, the second-2 step may include forming the high-temperature undoped GaN layer in the thickness of about 0.01 μm to about 1 μm, the second-3 step may include forming the compensation layer into which iron (Fe) or carbon (C) having a concentration of 1E18˜1E19/cm³ has been doped as the electron-trapping impurities in the thickness of about 0.01 μm to about 5 μm, and the second-4 step may include forming the channel layer in the thickness of about 10 nm to about 100 nm.

In the method of fabricating a heterojunction transistor in accordance with an exemplary embodiment of the present invention, the fourth step may include a fourth-1 step of forming the P type semiconductor layer on the entire surface of the first barrier layer by growing the first barrier layer and a fourth-2 step of forming the P type semiconductor layer patterned to be positioned in the gate control region by etching the P type semiconductor layer formed on the entire surface of the first barrier layer.

In the method of fabricating a heterojunction transistor in accordance with an exemplary embodiment of the present invention, the fourth step may include forming the P type semiconductor layer using a GaN or AlGaN semiconductor or an i-AlGaN semiconductor having a hole concentration of 5×10¹⁶/cm³ to 5×10¹⁸/cm³ through the implantation of impurities.

In the method of fabricating a heterojunction transistor in accordance with an exemplary embodiment of the present invention, the fifth step may include forming the second barrier layer from the first barrier layer through a growth process in the state in which the P type semiconductor layer has been formed in the gate control region.

In accordance with further an exemplary embodiment of the present invention, a method of fabricating a heterojunction transistor includes a first step of preparing a substrate; a second step of forming a channel layer, made of a first nitride-based semiconductor having a first energy bandgap, over the substrate; a third step of forming a first barrier layer, made of a second nitride-based semiconductor having a second energy bandgap different from the first energy bandgap, over the channel layer; a fourth step of forming a P type semiconductor layer in a gate control region on the first barrier layer; a fifth step of forming a second barrier layer, made of a third nitride-based semiconductor having a third energy bandgap different from the first energy bandgap, over the first barrier layer in the thickness equal to or lower than the thickness of the P type semiconductor layer using an insulating masking layer patterned to cover the P type semiconductor layer; and a sixth step of forming a gate electrode over the insulating masking layer placed over the P type semiconductor layer.

In the method of fabricating a heterojunction transistor in accordance with an exemplary embodiment of the present invention, the third step may include forming the first barrier layer in the thickness in which a 2DEG channel is not formed through the junction of the channel layer and the first barrier layer in the state in which a bias has not been applied to the gate electrode, and the fifth step may include forming the second barrier layer in the thickness in which the 2DEG channel is formed through the junction of the first barrier layer, the second barrier layer, and the channel layer in the state in which a bias has not been applied to the gate electrode.

In the method of fabricating a heterojunction transistor in accordance with an exemplary embodiment of the present invention, the third step may include forming the first barrier layer made of the second nitride-based semiconductor having the second energy bandgap greater than the first energy bandgap, and the fifth step may include forming the second barrier layer made of the third nitride-based semiconductor having the third energy bandgap greater than the first energy bandgap.

In the method of fabricating a heterojunction transistor in accordance with an exemplary embodiment of the present invention, the fifth step may include forming the second barrier layer in the thickness greater than the thickness of the first barrier layer. Here, the second barrier layer may be made of the third nitride-based semiconductor having the third energy bandgap identical with the second energy bandgap.

In the method of fabricating a heterojunction transistor in accordance with an exemplary embodiment of the present invention, the fifth step may include forming the second barrier layer using the third nitride-based semiconductor having the third energy bandgap greater than the second energy bandgap.

In the method of fabricating a heterojunction transistor in accordance with an exemplary embodiment of the present invention, the first nitride-based semiconductor may be made of GaN materials, and the second nitride-based semiconductor and the third nitride-based semiconductor may be made of AlₓGa₁₋ₓN materials. Here, the third nitride-based semiconductor may have a higher Al composition ratio higher than the second nitride-based semiconductor.

In the method of fabricating a heterojunction transistor in accordance with an exemplary embodiment of the present invention, the third step may include forming the first barrier layer made of the second nitride-based semiconductor having an Al composition ratio of about 5% to about 25% and formed in the thickness of about 3 nm to about 15 nm, and the fifth step may include forming the second barrier layer made of the third nitride-based semiconductor having an Al composition ratio of about 15% to about 100% and formed in the thickness of about 5 nm to about 30 nm.

In the method of fabricating a heterojunction transistor in accordance with an exemplary embodiment of the present invention, the fourth step may include forming the P type semiconductor layer in the thickness of about 10 nm to about 80 nm.

In the method of fabricating a heterojunction transistor in accordance with an exemplary embodiment of the present invention, the fourth step may include forming the P type semiconductor layer using a GaN or AlGaN semiconductor or an i-AlGaN semiconductor having a hole concentration of 5×10¹⁶/cm³ to 5×10¹⁸/cm³ through the implantation of impurities.

In the method of fabricating a heterojunction transistor in accordance with an exemplary embodiment of the present invention, the fourth step may include a fourth-1 step of forming the P type semiconductor layer on the entire surface of the first barrier layer by growing the first barrier layer and a fourth-2 step of forming the P type semiconductor layer patterned to be positioned in the gate control region by etching the P type semiconductor layer formed on the entire surface of the first barrier layer.

In the method of fabricating a heterojunction transistor in accordance with an exemplary embodiment of the present invention, the fifth step may include forming the second barrier layer through the growth of the first barrier layer in the state in which the P type semiconductor layer has been formed in the gate control region and the insulating masking layer has been formed on the P type semiconductor layer.

In accordance with an exemplary embodiment of the present invention, a heterojunction transistor includes a substrate; a channel layer formed over the substrate and made of a first nitride-based semiconductor having a first energy bandgap; a first barrier layer formed over the channel layer and made of a second nitride-based semiconductor having a second energy bandgap different from the first energy bandgap; a P type semiconductor layer formed in a gate control region of the first barrier layer; a second barrier layer formed over the first barrier layer in the thickness equal to or lower than of the thickness of the P type semiconductor layer; a gate electrode formed over the P type semiconductor layer; and a source electrode and a drain electrode formed over the second barrier layer.

The heterojunction transistor in accordance with an exemplary embodiment of the present invention may further include an insulating masking layer placed between the P type semiconductor layer and the gate electrode as a gate insulating film.

In the heterojunction transistor in accordance with an exemplary embodiment of the present invention, the first barrier layer or the second barrier layer may be doped with n type impurities.

In the heterojunction transistor in accordance with an exemplary embodiment of the present invention, the first barrier layer is formed in the thickness in which a 2DEG channel is not formed through the junction of the channel layer and the first barrier layer in the state in which a bias has not been applied to the gate electrode. The second barrier layer is formed in the thickness in which the 2DEG channel is formed through the junction of the first barrier layer, the second barrier layer, and the channel layer in the state in which a bias has not been applied to the gate electrode.

In the heterojunction transistor in accordance with an exemplary embodiment of the present invention, the first barrier layer may be made of the second nitride-based semiconductor having the second energy bandgap greater than the first energy bandgap, and the second barrier layer may be made of the third nitride-based semiconductor having the third energy bandgap greater than the first energy bandgap.

In the heterojunction transistor in accordance with an exemplary embodiment of the present invention, the second barrier layer may be made of the third nitride-based semiconductor having the third energy bandgap equal to the second energy bandgap and may be formed thicker than the first barrier layer.

In the heterojunction transistor in accordance with an exemplary embodiment of the present invention, the second barrier layer may be made of the third nitride-based semiconductor having the third energy bandgap greater than the second energy bandgap.

In the heterojunction transistor in accordance with an exemplary embodiment of the present invention, the first nitride-based semiconductor may be made of GaN materials, the second nitride-based semiconductor and the third nitride-based semiconductor may be made of AlₓGa₁₋ₓN materials, and the third nitride-based semiconductor may have a higher Al composition ratio higher than the second nitride-based semiconductor.

In the heterojunction transistor in accordance with an exemplary embodiment of the present invention, the first barrier layer may be made of the second nitride-based semiconductor having an Al composition ratio of about 5% to about 25% and formed in the thickness of about 3 nm to about 15 nm, and the second barrier layer may be made of the third nitride-based semiconductor having an Al composition ratio of about 15% to about 100% and formed in the thickness of about 5 nm to about 30 nm.

In the heterojunction transistor in accordance with another aspect of the present invention, the P type semiconductor layer has a thickness of 10 nm or more to 80 nm or less.

In the heterojunction transistor in accordance with an exemplary embodiment of the present invention, the P type semiconductor layer may be made of a GaN or AlGaN semiconductor or an i-AlGaN semiconductor having a hole concentration of 5×10¹⁶/cm³ to 5×10¹⁸/cm³ through the implantation of impurities.

A heterojunction transistor in accordance with an exemplary embodiment of the present invention may further include a buffer layer placed over the substrate, a high-temperature undoped GaN layer disposed over the buffer layer, and a compensation layer disposed over the high-temperature undoped GaN layer and made of a GaN semiconductor into which electron-trapping impurities have been doped. Here, wherein the channel layer may be disposed over the compensation layer and made of a high-quality GaN semiconductor having defect density of 5E8/cm² or less.

In the heterojunction transistor in accordance with an exemplary embodiment of the present invention, the substrate may be a sapphire substrate, the buffer layer may include a single AlGaN layer or a plurality of AlGaN layers having different Al composition ratios, the high-temperature undoped GaN layer may have a thickness of about 0.01 μm to about 1 μm, the compensation layer may be doped with iron (Fe) or carbon (C) having a concentration of 5E17˜1E19/cm³ as electron-trapping impurities and may be formed in the thickness of about 0.01 μm to about 5 μm, and the channel layer may have a thickness of about 10 nm to about 100 nm.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

The above and other objects, features and other advantages of the present invention will be more clearly understood from the following detailed description taken in conjunction with the accompanying drawings, in which:

FIGS. 1A, 1B, 1C, and 1D are process diagrams illustrating a method of fabricating a conventional heterojunction transistor having a gate recess structure.

FIG. 2 is a cross-sectional view of the conventional heterojunction transistor having a gate recess structure.

FIG. 3 is a cross-sectional view of a heterojunction transistor according to an exemplary embodiment of the present invention.

FIGS. 4A, 4B, 4C, and 4D are process diagrams illustrating a method of fabricating the heterojunction transistor of FIG. 3.

FIG. 5 is an exemplary diagram showing a relationship between the distance and energy of semiconductor layers that are subject to heterojunction in the heterojunction transistor of FIG. 3.

FIG. 6 is an exemplary diagram showing a relationship between the thickness of a barrier layer and a conduction band edge according to an aluminum (Al) composition ratio of the heterojunction transistor of FIG. 3.

FIG. 7 is an exemplary diagram showing a relationship between the thickness of a barrier layer of the heterojunction transistor of FIG. 3 and the electron density of 2DEG.

FIG. 8 is a cross-sectional view of a heterojunction transistor in accordance with an exemplary embodiment of the present invention.

FIG. 9 is a cross-sectional view of a heterojunction transistor in accordance with an exemplary embodiment of the present invention.

FIGS. 10A, 10B, 10C, and 10D are process diagrams illustrating a method of fabricating the heterojunction transistor shown in FIG. 9.

FIG. 11 is an exemplary diagram showing a relationship between the distance and energy of semiconductor layers that are subject to heterojunction in the heterojunction transistor of FIG. 9.

FIG. 12 is an exemplary diagram showing a relationship between the thickness of a barrier layer and a conduction band edge according to an aluminum (Al) composition ratio of the heterojunction transistor of FIG. 9.

FIG. 13 is an exemplary diagram showing a relationship between the thickness of the barrier layer of the heterojunction transistor shown in FIG. 9 and the electron density of 2DEG.

FIG. 14 is a cross-sectional view of a heterojunction transistor in accordance with an exemplary embodiment of the present invention.

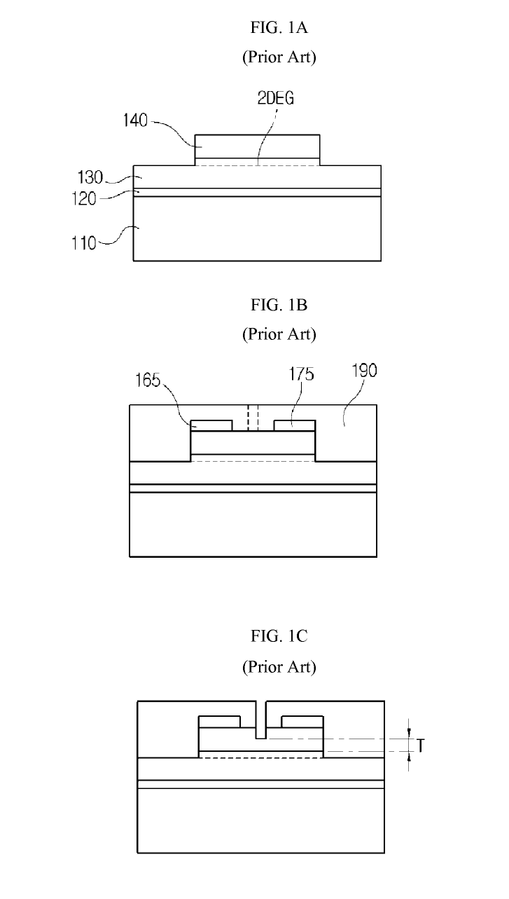

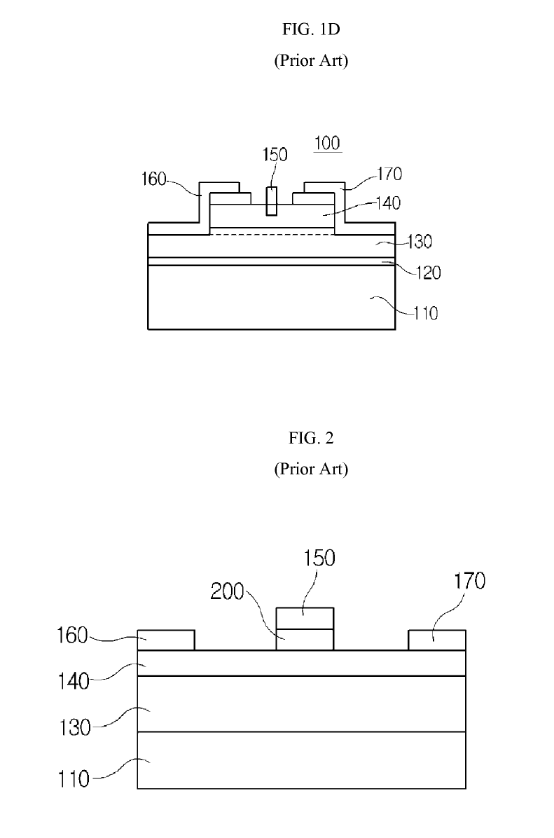

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Exemplary embodiments of the present invention are described in detail below with reference to the accompanying drawings.

In the drawings, the width, length, thickness, etc. of each element may have been enlarged for convenience. Furthermore, when it is described that one element is disposed ‘over’ or ‘on’ the other element, one element may be disposed ‘right over’ or ‘right on’ the other element or a third element may be disposed between the two elements. The same reference numbers are used throughout the specification to refer to the same or like parts. Furthermore, in the following embodiments, heterojunction transistor devices using a nitride gallium (GaN)-based semiconductor are illustrated, but the present invention is not limited thereto. The heterojunction transistor devices may be implemented using various types of existing nitride-based semiconductors if the present invention can be applied to the existing nitride-based semiconductors.

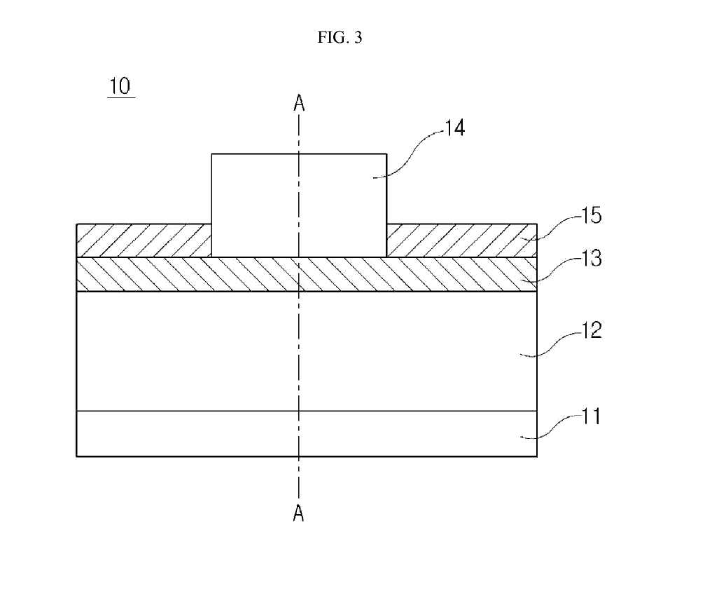

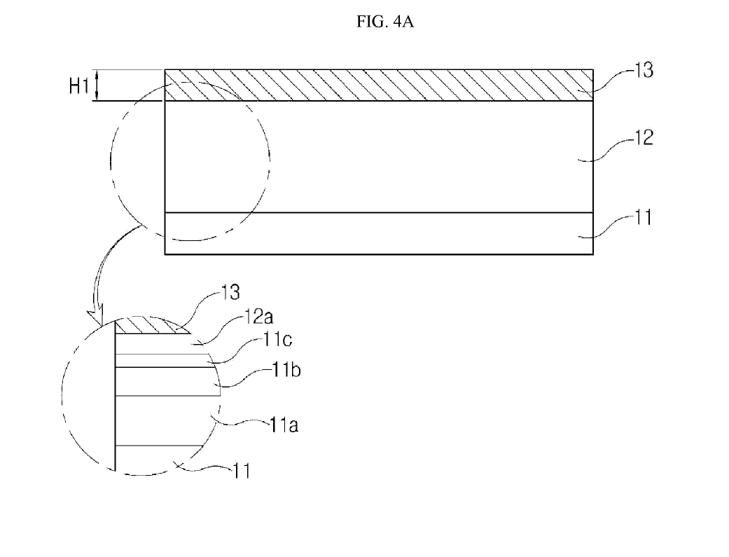

FIG. 3 is a cross-sectional view of a heterojunction transistor according to an exemplary embodiment of the present invention.

Referring to FIG. 3, the heterojunction transistor 10 may include a substrate 11, a channel layer 12, a first barrier layer 13, a gate electrode 14, and a second barrier layer 15.

The heterojunction transistor 10 according to the present exemplary embodiment has a barrier layer structure in which a barrier layer is divided into the first barrier layer 13 and the second barrier layer 15 regrown from the first barrier layer 13, and thus a recess can be formed in a switching control region (or a gate control region) without an etch process. Accordingly, device capabilities and reliability can be improved and a normally off characteristic can be implemented because problems that may occur in an etch process are removed.

The elements of the present invention are described in more detail herein. First, the substrate 11 is not specially limited to any substrate if a semiconductor layer can be grown on the substrate. For example, the substrate 11 may be implemented using a sapphire substrate, an AlN substrate, a GaN substrate, a SiC substrate, or an Si substrate.

The channel layer 12 is disposed on the substrate 11 and formed of a first nitride-based semiconductor having a first energy bandgap. The first nitride-based semiconductor includes GaN. The channel layer 12 forms a channel region for the migration of electrons depending on an electric field applied to the channel layer 12.

The channel layer 12 may have a thickness of about 10 nm or more to about 100 nm or less. If the thickness of the channel layer 12 is less than 10 nm, electron mobility may be reduced because the channel region for the migration of electrons is narrowed. If the thickness of the channel layer 12 exceeds 100 nm, a crack may occur due to lattice stress.

The channel layer 12 may be integrally formed with a buffer layer which functions to reduce a lattice mismatch between the substrate 11 and a semiconductor layer. Furthermore, the buffer layer, etc. may be included between the channel layer 12 and the substrate 11.

The first barrier layer 13 is disposed on the channel layer 12 and is made of a second nitride-based semiconductor having a second energy bandgap different from the first energy bandgap. The second nitride-based semiconductor includes AlₓGa₁₋ₓN, where 0.05≦x≦0.25.

The first barrier layer 13 has a sufficiently small thickness such that a Two-Dimensional Electron Gas (2DEG) channel is not formed near the interface between the first barrier layer 13 and the channel layer 12 in the state in which a bias has not been applied to the gate electrode 14. The reason why the first barrier layer 13 is formed to a small thickness is that the first barrier layer 13 is disposed to be subject to heterojunction with the channel layer 12, but the 2DEG channel is not formed at the interface due to the heterojunction. The structure of the present exemplary embodiment is different from that of the barrier layer of an existing heterojunction transistor in which the barrier layer is formed to a specific thickness or more in order to form a 2DEG channel at the interface between the barrier layer and a channel layer when the barrier layer is subject to be heterojunction with the channel layer.

The gate electrode 14 is disposed on the gate control region of the first barrier layer 13. The gate control region corresponds to a region of the first barrier layer 13 that faces the gate electrode 14 and that is disposed under the gate electrode 14. The gate electrode 14 may be made of materials that form a Schottky junction between the gate electrode 14, and the first barrier layer 13 and the second barrier layer 15. For example, the materials of the gate electrode 14 may include Ni, Pd, Au, Pt, or W.

The second barrier layer 15 is disposed on the gate non-control regions of the first barrier layer 13. The gate non-control regions correspond to regions of the first barrier layer 13 other than the gate control region. That is, the gate non-control regions correspond to the remaining regions other than the region in which the gate electrode 14 is placed on the first barrier layer 13.

When the second barrier layer 15 is disposed on the first barrier layer 13, the second barrier layer 15 has a second thickness in which a 2DEG channel is formed at the interface between the first barrier layer 13 and the channel layer 12 in the state in which a bias has not been applied to the gate electrode 14. The second thickness may be the same as or different from the first thickness of the first barrier layer 13. If the second thickness is greater than the first thickness, the materials of the second barrier layer 15 may be the same as those of the first barrier layer 13. The second thickness may be the same as or greater than the first thickness for the ease of process control because the first thickness may be relatively smaller the second thickness practically.

A source electrode and a drain electrode (refer to 160 and 170 of FIG. 2) may be formed on the second barrier layer 15. The source electrode and the drain electrode are disposed on both sides of the gate electrode with the gate electrode interposed between the source electrode and the drain electrode.

The heterojunction transistor 10 according to the present exemplary embodiment can solve problems inherent in the existing gate recess structure using an etch process because it includes the gate recess structure for implementing a normally off characteristic using the regrowth barrier layer structure including the first barrier layer and the second barrier layer. Furthermore, the heterojunction transistor 10 according to the present exemplary embodiment has advantages in that device reliability and the uniformity of device characteristics can be improved, the ease of control of electron density in 2DEG can be improved, and a fabricating process can be simplified because a discontinuous region in which 2DEG is rarely formed in a 2DEG channel can be effectively controlled.

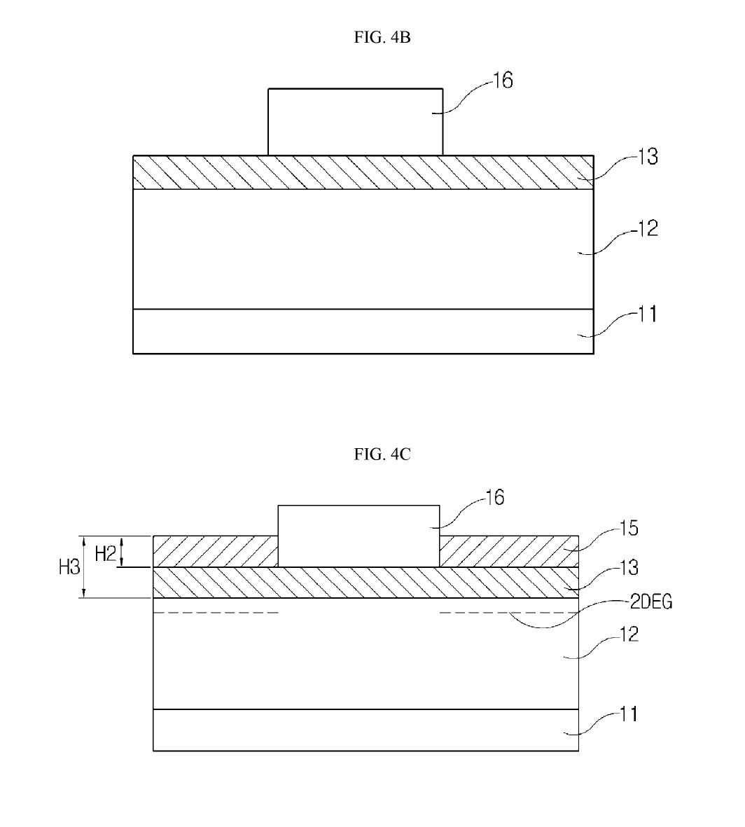

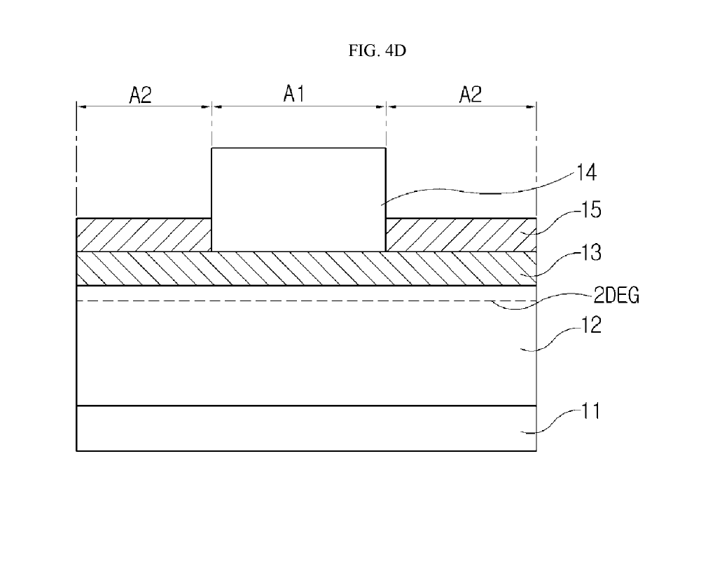

FIGS. 4A to 4D are process diagrams illustrating a method of fabricating the heterojunction transistor of FIG. 3.

First, as shown in FIG. 4A, the channel layer 12 having the first energy bandgap is formed on the substrate 11, and the first barrier layer 13 having the second energy bandgap is formed in the first thickness H1 on the channel layer 12. Here, the channel layer 12 is made of the first nitride-based semiconductor grown from the substrate 11, and the first barrier layer 13 is made of the second nitride-based semiconductor grown from the channel layer 12 in a heterojunction structure. The first energy bandgap may be the same as the second energy bandgap.

In the present exemplary embodiment, the substrate 11 may be a sapphire substrate, the channel layer 12 may be made of GaN materials, and the first barrier layer 13 may be made of AlₓGa₁₋ₓN materials. In such a case, the second energy bandgap may be greater than the first energy bandgap.

Furthermore, the first barrier layer 13 is formed at a thickness that does not form a 2DEG channel due to heterojunction between the first barrier layer 13 and the channel layer 12 in the state in which a bias has not been applied to the gate electrode to be formed in a subsequent process. The first barrier layer 13 may be formed using AlGaN materials having an aluminum (Al) composition ratio of 5% to less than 25%, to a thickness of about 3 nm to about 15 nm in the first thickness H1, by taking a proper aluminum (Al) concentration and thickness into consideration.

The channel layer 12 can be formed through a continuous film growth process from the buffer layer that functions to reduce a lattice mismatch between the substrate 11 and a semiconductor layer. Furthermore, the channel layer 12 may be formed over the substrate 11 with other functional layers, such as the buffer layer, interposed between the channel layer 12 and the substrate 11. For example, in a modified example of the present exemplary embodiment, the heterojunction transistor 10 may be implemented to include a buffer layer 11a formed on the substrate 11, a high-temperature undoped GaN layer 11b formed on the buffer layer 11a, a compensation layer 11c formed on the high-temperature undoped GaN layer 11b, and a channel layer 12a formed on the compensation layer 11c.

In the aforementioned case, the buffer layer 11a may include a single AlGaN layer or a plurality of AlGaN layers having different Al composition ratios. The high-temperature undoped GaN layer 11b functions to planarize the top of the buffer layer 11a and may have a thickness of about 0.01 μm to about 1 μm. The compensation layer 11c functions to block electrons from the channel layer 12. The compensation layer 11c may be doped with iron (Fe) or carbon (C) having a concentration of 5E17/cm³˜1E19/cm³ as electron-trapping impurities, for example and may have a thickness of about 0.01 μm to about 5 μm. Furthermore, the channel layer 12a may be formed of a high-quality channel GaN layer and may have a thickness of greater than 0 to about 100 nm.

Next, as shown in FIG. 4B, an insulating masking layer 16 is selectively formed in the gate control region A1 of the first barrier layer 13.

The insulating masking layer 16 may be made of insulating materials, such as oxide or nitride. For example, silicon oxide (SiO₂) may be used as the insulating materials. The insulating masking layer 16 may have a thickness of about 10 nm to about 500 nm. Such a thickness range has been set by taking the ease of process control and a rapid process into consideration.

A process of forming the insulating masking layer 16 may include forming an insulating layer on the channel layer 12, forming a photoresist layer formed on the insulating layer, removing part of the insulating layer in the gate non-control regions other than the gate control region A1 through a wet etch process, and forming the insulating masking layer 16 by removing the photoresist layer.

If the first barrier layer 13 is made of AlGaN materials, a surface state of the first barrier layer 13 may not be affected although the first barrier layer 13 is exposed to wet etching because a Ga-surface is grown into an upper surface layer. That is, if a wet etch process is used to form the insulating masking layer 16, damage may be prevented after etching a surface of the barrier layer that may occur in an existing recess formation process using dry etching in order to implement a normally off characteristic.

Next, as shown in FIG. 4C, the second barrier layer 15 having a third energy bandgap is formed on the first barrier layer 13. The second barrier layer 15 may be made of a third nitride-based semiconductor and formed at a second thickness H2 that is the same as or less than the thickness of the insulating masking layer 16.

In the present exemplary embodiment, the second barrier layer 15 may be formed at the second thickness H2 to a thickness of about 5 nm to about 30 nm using AlₓGa₁₋ₓN materials having an Al composition ratio of about 15% to 100%.

If the second barrier layer 15 has the same Al composition ratio as the first barrier layer 13 or the third energy bandgap of the second barrier layer 15 is the same as the second energy bandgap of the first barrier layer 13, the second thickness H2 of the second barrier layer 15 may be greater than the first thickness H1 of the first barrier layer 13. In this case, the third thickness H3 of the barrier layer, that is, the sum of the first thickness H1 of the first barrier layer 13 having a relatively small thickness and the second thickness H2 of the second barrier layer 15 disposed on the first barrier layer 13, can become a thickness in which a 2DEG channel can be properly formed at the interface between the channel layer 12 and the first barrier layer 13.

Next, as shown in FIG. 4D, the insulating masking layer 16 is removed, and the gate electrode 14 is formed on part of the first barrier layer 13 that is exposed in the gate control region A1.

For example, a method of forming the gate electrode 14 may include forming the gate electrode 14 by patterning a photoresist so that an opening part corresponding to the gate control region A1 is present in the gate control region A1 from which the insulating masking layer 16 has been removed and the gate non-control regions A2 and depositing metal materials in the recess of the gate control region A1 through the patterned photoresist.

Before or after the gate electrode 14 is formed, a source electrode and a drain electrode subject to an ohmic contact with the second barrier layer 15 may be formed on the second barrier layer 15.

As described above, in accordance with the method of fabricating the heterojunction transistor according to the present exemplary embodiment, the first barrier layer 13 is formed on the channel layer, and the second barrier layer 15 is regrown and formed only in the remaining regions (i.e., the gate non-control regions) other than the gate control region A1 on the first barrier layer 13. Accordingly, a method of forming a normally off heterojunction transistor having a gate recess structure not using an etch process can be effectively implemented.

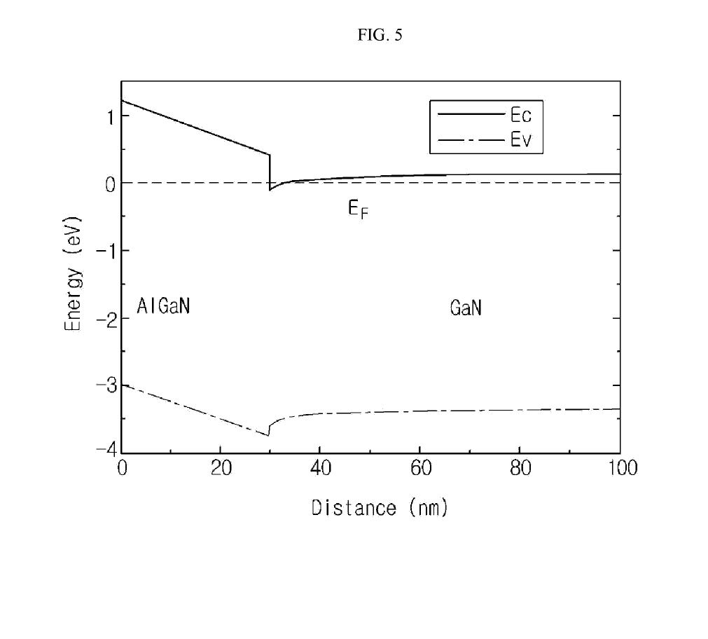

FIG. 5 is an exemplary diagram showing a relationship between the distance and energy of semiconductor layers that are subject to heterojunction in the heterojunction transistor of FIG. 3.

FIG. 5 shows a relationship between the distance extended along line A-A in the heterojunction transistor of FIG. 3 and energy of the heterojunction semiconductor layers.

As shown in FIG. 5, if the channel layer 12 made of a GaN semiconductor and the barrier layer made of an AlGaN semiconductor are subject to heterojunction, a high-concentration 2DEG channel attributable to a polarization effect is formed in a conduction band edge part due to a difference between energy bandgaps at the interface of a conduction band Ec and a valence band Ev between the two semiconductor materials. Such 2DEG may have an excellent electron transport characteristic in the active region of a semiconductor device, such as a transistor, because the 2DEG is placed in an energy level lower than a Fermi energy level E_{F}.

As described above, the 2DEG is used. Furthermore, in order to implement a normally off characteristic, a regrowth barrier layer structure in which the second barrier layer 15 is formed using the thin first barrier layer 13 so as to implement a normally off transistor using a 2DEG channel is used in the heterojunction transistor 10 according to the present exemplary embodiment. That is, the heterojunction transistor 10 according to the present exemplary embodiment has a regrowth barrier layer structure (corresponding to a gate recess structure) in which the second barrier layer 15 is formed by selectively regrowing the first barrier layer 13 in the gate non-control regions A2. Accordingly, a heterojunction transistor having an excellent normally off characteristic can be implemented by effectively forming a discontinuous region in the 2DEG channel.

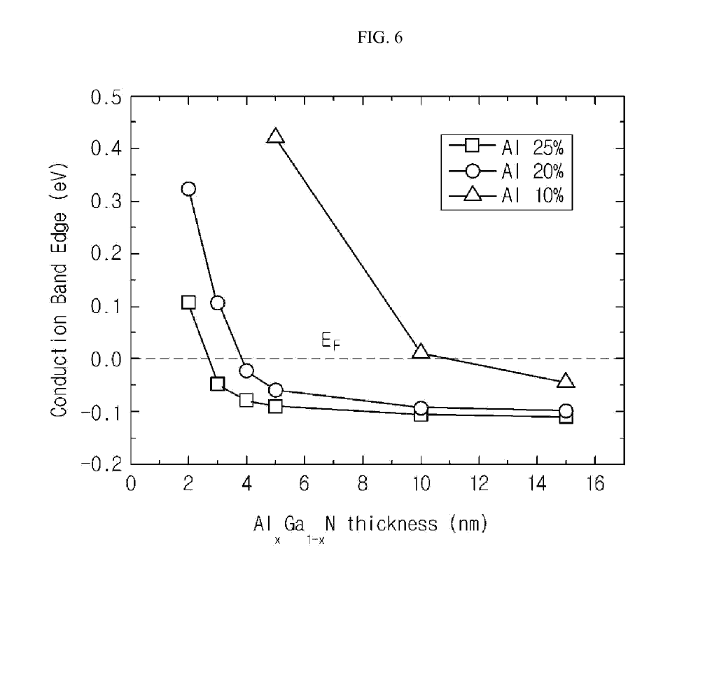

FIG. 6 is an exemplary diagram showing a relationship between the thickness of the barrier layer and a conduction band edge according to an Al composition ratio of the heterojunction transistor of FIG. 3.

As shown in FIG. 6, in an AlₓGa₁₋ₓN barrier layer that forms the first barrier layer 13 and the second barrier layer 15, the position of a conduction band edge may be different depending on an Al composition ratio and a thickness.

Accordingly, when forming a barrier layer to a small thickness, an electron concentration of 2DEG can be increased by raising an Al composition ratio because the electron concentration can be reduced. Furthermore, when it is difficult to form the barrier layer to a small thickness, there may be free from a limit to the thickness because the barrier layer having a low Al composition ratio is formed. That is, in the present invention, in order to provide the heterojunction transistor which has the gate recess structure formed without using an etch process and also properly uses a 2DEG channel according to heterojunction, the barrier layer grown from the channel layer in the heterojunction structure is divided into two or more steps and regrown.

In a process of dividing the barrier layer into the first barrier layer 13 and the second barrier layer 15 and regrowing the first barrier layer 13 and the second barrier layer 15, an electron concentration may be decreased if the thickness of the barrier layer becomes thin, and an electron concentration may be increased if the thickness of the barrier layer becomes thick, but a crack may be generated in the barrier layer due to lattice stress. For example, at an Al concentration of about 25% or more, a crack attributable to lattice stress may be generated before relaxation occurs when the thickness of the barrier layer is increased.

Accordingly, there is a need for preferred conditions for forming the aforementioned 2DEG channel and the gate recess structure. Exemplary conditions according to the present exemplary embodiment are described below.

First, if an Al composition ratio is x=0.25 (Al 25%) in a barrier layer made of an AlₓGa₁₋ₓN nitride-based semiconductor, when the thickness of the barrier layer exceeds about 3 nm, a conduction band edge is placed in an energy level lower than a Fermi energy level E_{F}.

Accordingly, there may be a difficulty in process control or the formation of a uniform barrier layer when forming the barrier layer into the first barrier layer 13 and the second barrier layer 15 regrown from the first barrier layer 13. That is, if the Al composition ratio of the AlₓGa₁₋ₓN barrier layer is set in the range of 25% to 100%, a critical thickness is exceeded and a 2DEG channel characteristic may be significantly deteriorated because a crack is generated.

Furthermore, in the case of the second barrier layer, if ‘x’ in AlₓGa₁₋ₓN regrown from the first barrier layer 13 becomes 1, a gallium (Ga) composition ratio becomes 0, and thus the second barrier layer becomes an AlN layer. In such a case, the second barrier layer 15 made of AlN may have a thickness of about 5 nm or less by taking the critical thickness of the AlN layer into consideration. This is because if the thickness of the AlN layer exceeds 5 nm, a crack may be generated in the AlN layer. Furthermore, if the second barrier layer 15 is formed of a thin layer, a problem in which positive charges are accumulated on a surface may be generated, and process control may be relatively difficult.

The first barrier layer 13 grown from the GaN channel layer 12 may have an Al composition ratio of less than 25% by taking a relationship between the aforementioned Al composition ratio and the thickness of the barrier layer into consideration. Furthermore, the Al composition ratio of the first barrier layer 13 may be about 5% or more by taking the ease of process control and lattice stress attributable to an increase of the thickness into consideration in an Al composition ratio of less than 25%.

When the Al composition ratio (i.e., in a range of about 5% to 25%) is taken into consideration, the thickness of the first barrier layer 13 may be about 3 nm to about 15 nm.

Furthermore, the Al composition ratio and thickness of the second barrier layer 15 may be determined depending on the Al composition ratio and thickness of the first barrier layer 13. The second barrier layer 15 may have an Al composition ratio of about 15% to 100% and a thickness of about 5 nm to about 30 nm. In the second barrier layer 15 made of a nitride-based semiconductor, if the thickness of the second barrier layer 15 is less than 5 nm, channel resistance may be increased because an electron concentration of 2DEG is low. If the thickness of the second barrier layer 15 exceeds 30 nm, a crack may be generated due to lattice stress and a lot of time may be taken for a process of forming the second barrier layer 15.

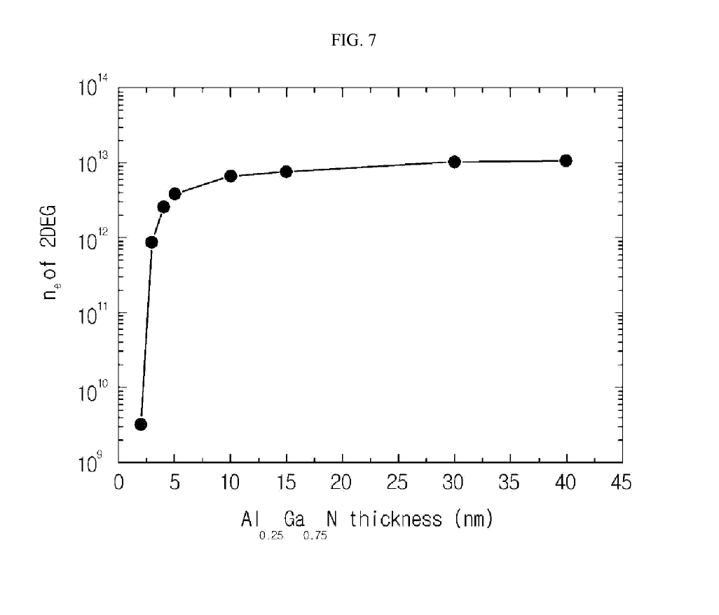

FIG. 7 is an exemplary diagram showing a relationship between the thickness of a barrier layer of the heterojunction transistor of FIG. 3 and the electron density of 2DEG.

As shown in FIG. 7, if the thickness of the barrier layer made of an AlₓGa₁₋ₓN nitride-based semiconductor becomes thin, the electron density nₑ of the 2DEG channel may be suddenly decreased in a specific thickness or less (e.g., about 3˜5 nm). That is, if the thickness of the AlGaN barrier layer having a specific aluminum (Al) concentration (e.g., 25%) is smaller than the specific thickness, a discontinuous region in which the 2DEG channel is not formed may be formed because spontaneous polarization and a piezoelectric effect are reduced in the 2DEG channel.

By taking a possible formation of the discontinuous region into consideration, in the regrowth barrier layer structure of the present exemplary embodiment, first, the thickness of the first barrier layer 13 from the channel layer 12 is formed in a thickness in which the 2DEG channel has not been formed when the first barrier layer 13 is subject to heterojunction with the channel layer 12. Thereafter, the second barrier layer 15 regrown in the gate non-control regions A2 of the first barrier layer 13 is formed in a thickness in which the 2DEG channel has been formed when the channel layer 12 is subject to heterojunction with the barrier layer (i.e., the first and the second barrier layers 13 and 15). Accordingly, exemplary embodiments of the present invention may provide the heterojunction transistor having an excellent normally off characteristic not including etch damage through the recess gate structure of the second barrier layer that is selectively grown from the thin first barrier layer using the insulating masking layer under the gate electrode as a mask.

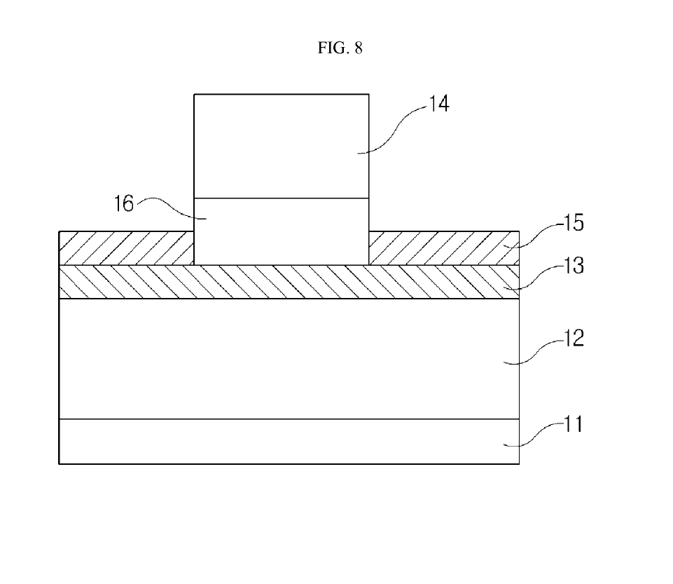

FIG. 8 is a cross-sectional view of a heterojunction transistor in accordance with an exemplary embodiment of the present invention.

Referring to FIG. 8, the heterojunction transistor has a Metal Insulator Semiconductor (MIS)-Heterojunction Field Effect Transistor (HFET) structure and includes the substrate 11, the channel layer 12, the first barrier layer 13, the gate electrode 14, the second barrier layer 15, and the insulating masking layer 16. Accordingly, a recess structure can be formed in a switching control region (or a gate control region) without an etch process because a barrier layer is divided into the first barrier layer 13 and the second barrier layer 15 regrown from the first barrier layer 13, and problems occurring in an etch process can be prevented and a normally off characteristic can also be implemented because the gate electrode 14 is disposed on the recess structure in which the insulating masking layer 16 is placed.

The heterojunction transistor according to the present exemplary embodiment is substantially the same as the heterojunction transistor described with reference to FIG. 3 except that the insulating masking layer 16 remains in the gate recess structure, and thus a redundant description thereof is omitted.

The insulating masking layer 16 may be implemented by controlling subsequent processes such that an insulating film placed over the first barrier layer 13 is not removed when forming the second barrier layer 15 in the heterojunction transistor fabricated using the method described with reference to FIGS. 4A to 4D. If a case where a manufacturing process becomes more complicated is not taken into consideration, however, the insulating masking layer 16 may be formed into a gate insulating film using additional insulating materials after being removed as in the method described with reference to FIGS. 4A to 4D.

The heterojunction transistor according to the present exemplary embodiment shows a high threshold voltage characteristic and a low gate leakage characteristic owing to the insulating masking layer 16 that functions as the gate insulating film placed between the gate electrode 14 and the channel layer 13, which may simplify a manufacturing process because a process of removing the insulating masking layer is omitted, as compared with the heterojunction transistor of FIG. 3.

In accordance with the aforementioned exemplary embodiments, as described above, the first barrier layer 13 subject to heterojunction with the channel layer 12 is thinly formed and the second barrier layer 15 is selectively regrown on the thin first barrier layer 13. Accordingly, the heterojunction transistor having a new regrowth recess gate structure with a reliable and normally-off characteristic can be implemented, the flexibility of a process can be improved because there is no limit to a composition ratio and thickness of the barrier layer, and reappearance can be improved because device characteristics become more uniform.

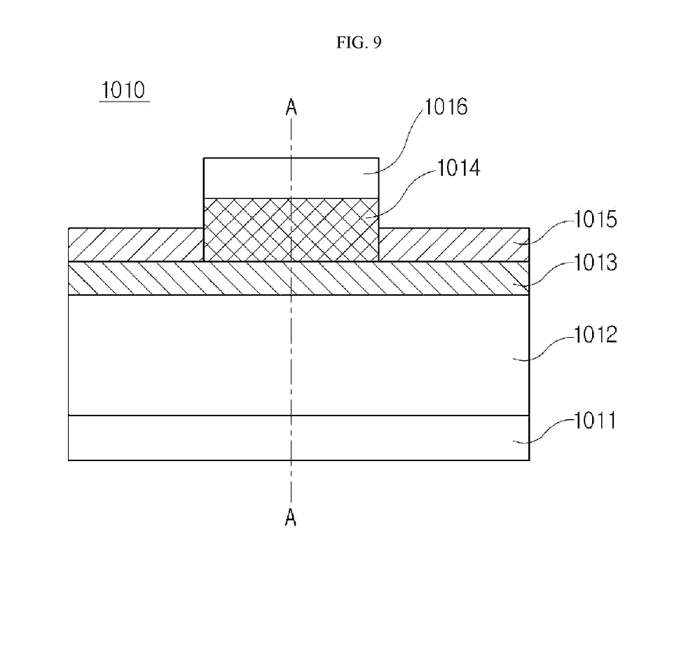

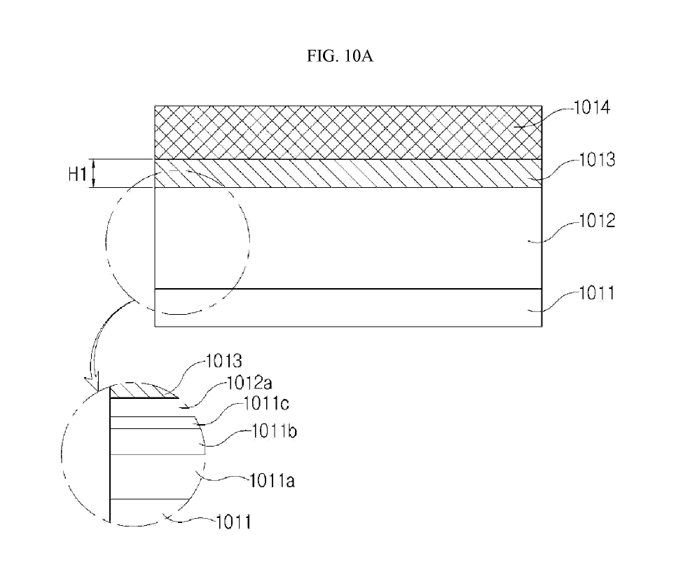

FIG. 9 is a cross-sectional view of a heterojunction transistor in accordance with an exemplary embodiment of the present invention.

Referring to FIG. 9, the heterojunction transistor 1010 may include a substrate 1011, a channel layer 1012, a first barrier layer 1013, a P type semiconductor layer 1014, a second barrier layer 1015, and a gate electrode 1016.

In the heterojunction transistor 1010 according to the present exemplary embodiment, the P type semiconductor layer 1014 grown from the first barrier layer 1013 is formed in a gate control region (i.e., a switching control region), a recess barrier layer structure is formed using the second barrier layer 1015 regrown from the first barrier layer 1013 in regions (i.e., gate non-control regions) other than the gate control region on the channel layer 1012 using the P type semiconductor layer 1014, and a recess is formed in the gate control region without an etch process. Accordingly, problems occurring in an etch process may be avoided, device capabilities and reliability can be improved, and a normally off characteristic can be implemented.

In particular, the heterojunction transistor 1010 according to the present exemplary embodiment can improve a drain current characteristic, a threshold voltage, and an interfacial characteristic between the gate electrode and the channel layer as compared with an existing Metal Insulator Semiconductor Heterojunction Field Effect Transistor (MIS-HFET) structure.

The elements of the present exemplary embodiment are described in more detail below. First, the substrate 1011 is not specially limited to any substrate if a semiconductor layer can be grown on the substrate. The substrate 1011 may be implemented using a sapphire substrate, an AlN substrate, a GaN substrate, a SiC substrate, or a Si substrate.

The channel layer 1012 is disposed on the substrate 1011 and is formed of a first nitride-based semiconductor having a first energy bandgap. The first nitride-based semiconductor includes GaN. The channel layer 1012 forms a channel region for the migration of electrons depending on an electric field applied to the channel layer 1012.

The channel layer 1012 may have a thickness of about 10 nm to about 100 nm. If the thickness of the channel layer 1012 is less than 10 nm, electron mobility may be reduced because the channel region for the migration of electrons is narrowed. If the thickness of the channel layer 1012 exceeds 100 nm, a crack may occur due to lattice stress.

The channel layer 1012 may be integrally formed with a buffer layer which functions to reduce a lattice mismatch between the substrate 1011 and a semiconductor layer. Furthermore, the buffer layer, etc. may be included between the channel layer 1012 and the substrate 1011.

The first barrier layer 1013 is disposed on the channel layer 1012 and is made of a second nitride-based semiconductor having a second energy bandgap different from the first energy bandgap. The second nitride-based semiconductor includes AlₓGa₁₋ₓN.

The first barrier layer 1013 has a small thickness so that a 2DEG channel is not formed near the interface between the first barrier layer 1013 and the channel layer 1012 in the state in which a bias has not been applied to the gate electrode 1016. The first barrier layer 1013 is formed to a small thickness so that the first barrier layer 1013 is disposed to be subject to heterojunction with the channel layer 1012, but the 2DEG channel is not formed at the interface due to the heterojunction. The structure of the present exemplary embodiment is different from that of the barrier layer of an existing heterojunction transistor in which the barrier layer is formed to a specific thickness or more in order to form a 2DEG channel at the interface between the barrier layer and a channel layer when the barrier layer is subject to be heterojunction with the channel layer.

The P type semiconductor layer 1014 is disposed in the gate control region of the heterojunction transistor on the first barrier layer 1013. The P type semiconductor layer 1014 functions to rearrange a Fermi level that is formed by the heterojunction of the channel layer 1012 and the first barrier layer 1013.

In accordance with the action of the P type semiconductor layer 1014, a potential well of a valence band that is present near the interface of the channel layer 1012 and the first barrier layer 1013 moves over a Fermi level. Accordingly, a discontinuous region in which 2DEG is not formed can be formed in a 2DEG channel that is formed near the interface of the channel layer 1012 and the first barrier layer 1013 by means of the junction of the channel layer 1012, the first barrier layer 1013, and the second barrier layer 1015.

The P type semiconductor layer 1014 may have a height of 10 nm to 80 nm. The P type semiconductor layer 1014 may be made of a GaN or AlGaN semiconductor or an i-AlGaN semiconductor having a hole concentration of 5×10¹⁶/cm³ to 5×10¹⁸/cm³ through the implantation of impurities. Furthermore, in some exemplary embodiments, the P type semiconductor layer 1014 may be made of a nitride-based semiconductor using a binary system, such as undoped GaN or InN, a ternary system, such as InGaN, or a quaternary system, such as AlInGaN.

The second barrier layer 1015 is disposed on the gate non-control regions of the first barrier layer 1013. The gate non-control regions correspond to regions of the first barrier layer 1013 other than the gate control region. That is, the gate non-control regions correspond to the remaining regions other than the region in which the gate electrode 1016 is placed on the first barrier layer 1013.

When the second barrier layer 1015 is disposed on the first barrier layer 1013, the second barrier layer 1015 has a second thickness in which a 2DEG channel is formed at the interface between the first barrier layer 1013 and the channel layer 1012 in the state in which a bias has not been applied to the gate electrode 1016. The second thickness may be the same as or different from the first thickness of the first barrier layer 1013. If the second thickness is greater than the first thickness, the materials of the second barrier layer 1015 may be the same as those of the first barrier layer 1013. The second thickness may be the same as or greater than the first thickness for the ease of process control because the first thickness is relatively smaller the second thickness practically.

The gate electrode 1016 is disposed on the gate control region of the first barrier layer 1013. The gate control region corresponds to a region of the first barrier layer 1013 that faces the gate electrode 1016 and that is disposed under the gate electrode 1016. The gate electrode 1016 may be made of materials that form a Schottky junction between the gate electrode 1016, and the first barrier layer 1013 and the second barrier layer 1015. For example, the materials of the gate electrode 1016 may include Ni, Pd, Au, Pt, or W.

A source electrode and a drain electrode may be disposed on both sides of the gate electrode with the gate electrode interposed between the source electrode and the drain electrode. The source electrode and the drain electrode (refer to 1160 and 1170 of FIG. 8) may be formed in such a way as to be in ohmic contact with the second barrier layer 1015.

In the heterojunction transistor 1010 according to the present exemplary embodiment, the second barrier layer 1015 is regrown from the thin first barrier layer 1013 using the P type semiconductor layer 1014 formed in the gate control region, and the gate recess structure is formed in the gate control region without using an etch process. Accordingly, problems inherent in an existing gate recess structure using an etch process can be solved, a highly reliable and normally-off characteristic can be implemented through the P type semiconductor layer, and a discontinuous region in which 2DEG is rarely formed in a Two-Dimensional Electron Gas (2DEG) channel can be stably controlled.

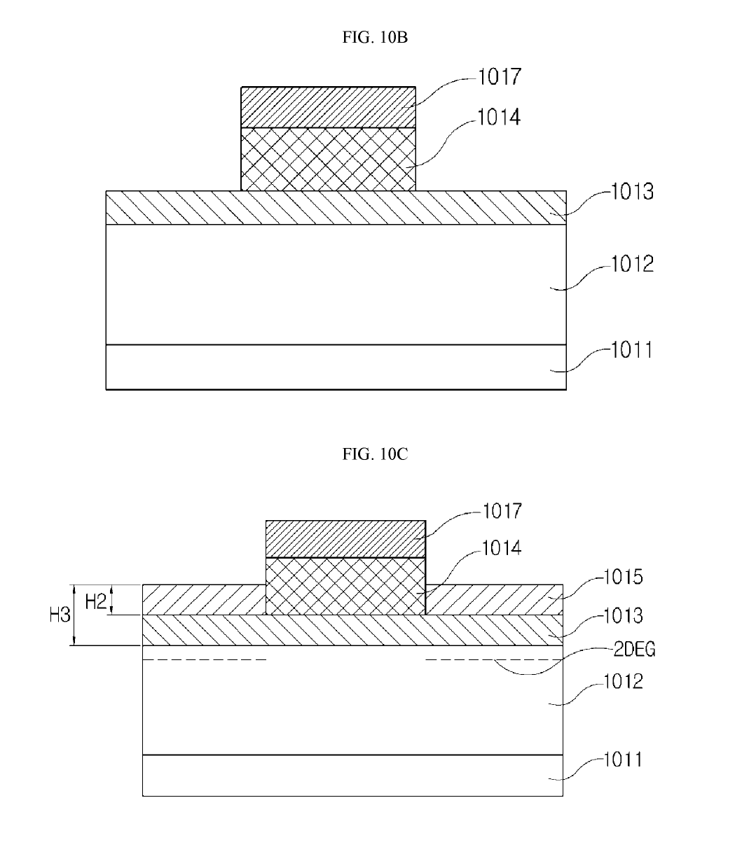

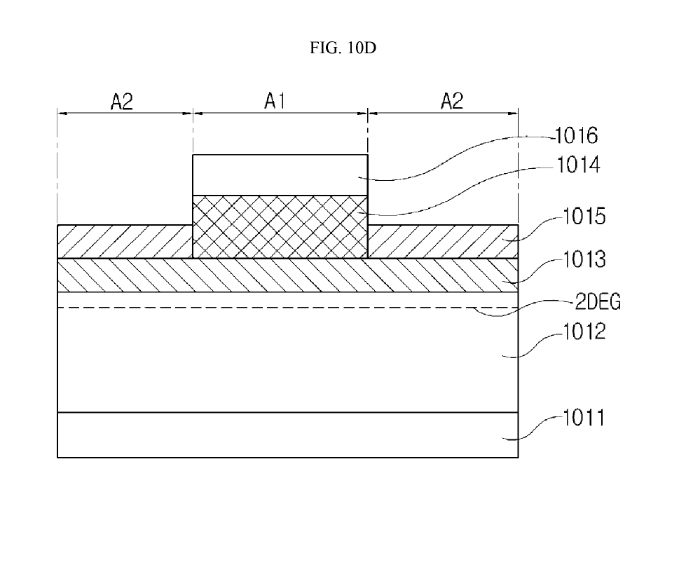

FIGS. 10A to 10D are process diagrams illustrating a method of fabricating the heterojunction transistor shown in FIG. 9.

First, as shown in FIG. 10A, the channel layer 1012 having the first energy bandgap is grown on the substrate 1011, the first barrier layer 1013 having the second energy bandgap is grown to the first thickness H1 on the channel layer 1012, and the P type semiconductor layer 1014 is grown on the first barrier layer 1013.

A process of forming the channel layer 1012, the first barrier layer 1013, and the P type semiconductor layer 1014 over the substrate 1011 may be performed by a continuous process within a chamber for film growth. In such a case, the P type semiconductor layer 1014 and the first barrier layer 1013 have an excellent interfacial characteristic.

Here, the channel layer 1012 is made of a first nitride-based semiconductor grown from the substrate 1011, and the first barrier layer 1013 is made of a second nitride-based semiconductor grown from the channel layer 1012 in a heterojunction structure. The first energy bandgap may be the same as the second energy bandgap.

The substrate 1011 may be a sapphire substrate, the channel layer 1012 may be made of GaN materials, the first barrier layer 1013 may be made of AlₓGa₁₋ₓN materials, and the P type semiconductor layer 1014 may be formed of a nitride-based semiconductor layer formed by doping a small amount of impurities, such as Mn or Zn, into GaN or AlGaN. In such a case, the second energy bandgap may be greater than the first energy bandgap

Furthermore, the first barrier layer 1013 is formed at a thickness that does not form a 2DEG channel due to heterojunction between the first barrier layer 1013 and the channel layer 1012 in the state in which a bias has not been applied to the gate electrode to be formed in a subsequent process. The first barrier layer 1013 may be formed using AlGaN materials having an Al composition ratio of 5% to 25%, to a thickness of about 3 nm to about 15 nm in the first thickness H1 by taking a proper aluminum (Al) concentration and thickness into consideration.

The channel layer 1012 can be formed through a continuous film growth process from the buffer layer that functions to reduce a lattice mismatch between the substrate 1011 and a semiconductor layer. Furthermore, the channel layer 1012 may be formed over the substrate 1011 with other functional layers, such as the buffer layer, interposed between the channel layer 1012 and the substrate 1011. For example, in a modified example of the present exemplary embodiment, the heterojunction transistor 1010 may include a buffer layer 1011a formed on the substrate 1011, a high-temperature undoped GaN layer 1011b formed on the buffer layer 101 la, a compensation layer 1011c formed on the high-temperature undoped GaN layer 1011b, and a channel layer 1012a formed on the compensation layer 1011c.

The buffer layer 1011a may include a single AlGaN layer or a plurality of AlGaN layers having different Al composition ratios. The high-temperature undoped GaN layer 1011b functions to planarize the top of the buffer layer 1011a and may have a thickness of about 0.01 μm to about 1 μm. The compensation layer 1011c functions to block electrons from the channel layer 1012. The compensation layer 1011c may be doped with iron (Fe) or carbon (C) having a concentration of 5E17/cm³˜1E19/cm³ as electron-trapping impurities, for example and may have a thickness of about 0.01 μm to about 5 μm. Furthermore, the channel layer 1012a may be formed of a high-quality channel GaN layer and may have a thickness of greater than 0 to about 100 nm.

Next, as shown in FIG. 10B, the P type semiconductor layer 1014 is formed in the gate control region A1 of the first barrier layer 1013.

The P type semiconductor layer 1014 may be formed by coating an insulating film and removing the remaining insulating film so that the insulating film covering the P type semiconductor layer 1014 placed in the gate control region A1 remains. The insulating film present on the P type semiconductor layer 1014 corresponds to an insulating masking layer 1017.

A process of forming the insulating masking layer 1017 may include forming an insulating layer on the channel layer 1012, forming a photoresist layer formed on the insulating layer, removing part of the insulating layer in the gate non-control regions other than the gate control region A1 through a wet etch process, and forming the insulating masking layer 1017 by removing the photoresist layer.

If the first barrier layer 1013 is made of AlGaN materials, a surface state of the first barrier layer 1013 may not be affected although the first barrier layer 1013 is exposed to wet etching because a Ga-surface is grown into an upper surface layer. That is, if a wet etch process is used to form the insulating masking layer 1017, damage may be prevented after etching a surface of the barrier layer that occurs in an existing recess formation process of forming a recess using dry etching in order to implement a normally off characteristic

The insulating masking layer 1017 may be made of insulating materials, such as oxide or nitride. For example, silicon oxide (SiO₂) may be used as the insulating materials. The insulating masking layer 1017 may have a thickness of about 10 nm to about 500 nm. Such a thickness range has been set by taking the ease of process control and a rapid process into consideration.

Next, as shown in FIG. 10C, the second barrier layer 1015 having a third energy bandgap is formed on the first barrier layer 1013. The second barrier layer 1015 may be made of a third nitride-based semiconductor and formed at a second thickness H2 that is the same as or less than the thickness of the P type semiconductor layer 1014.

In the present exemplary embodiment, the second barrier layer 1015 may be formed to a thickness of about 5 nm to about 30 nm at the second thickness H2 using AlₓGa₁₋ₓN materials having an Al composition ratio of about 15% to 100%. In particular, the second barrier layer 1015 is made of an n type nitride-based semiconductor into which a specific amount of n type impurities (i.e., donor) has been doped. In such a case, the second barrier layer 1015 can improve device characteristics by raising electron density in the 2DEG channel.

If the second barrier layer 1015 has the same Al composition ratio as the first barrier layer 1013 or the third energy bandgap of the second barrier layer 1015 is the same as the second energy bandgap of the first barrier layer 1013, the second thickness H2 of the second barrier layer 1015 may be greater than the first thickness H1 of the first barrier layer 1013. In this case, the third thickness H3 of the barrier layer, that is, the sum of the first thickness H1 of the first barrier layer 1013 having a relatively small thickness and the second thickness H2 of the second barrier layer 1015, can become a thickness in which a 2DEG channel can be properly formed at the interface between the channel layer 1012 and the first barrier layer 1013.

Next, as shown in FIG. 10D, the insulating masking layer 1017 is removed, and the gate electrode 1016 is formed on the P type semiconductor layer 1014 exposed in the gate control region A1.

The gate electrode 1016 is made of materials that come in a Schottky-contact with the P type semiconductor layer 1014. For example, the gate electrode 1016 may be made of Ni/Au or Pd/Au.

For example, a method of forming the gate electrode 1016 may include forming the gate electrode 1016 by patterning a photoresist so that an opening part corresponding to the gate control region A1 is present in the gate control region A1 from which the insulating masking layer 1017 has been removed and the gate non-control regions A2 and depositing metal materials in the P type semiconductor layer 1014 of the gate control region A1 through the patterned photoresist.

When a proper bias is applied to the gate electrode 1016, 2DEG may be formed in a portion near the boundary of the channel layer 1012 and the first barrier layer 1013 under the gate electrode 1016.

Before or after the gate electrode 1016 is formed, a source electrode and a drain electrode subject to an ohmic contact with the second barrier layer 1015 may be formed on the second barrier layer 1015.

In accordance with the method of fabricating the heterojunction transistor according to the present exemplary embodiment, the channel layer 1012, the thin first barrier layer 1013, and the P type semiconductor layer 1014 are grown over the substrate 1011 through a continuous process within a chamber, and the second barrier layer for forming 2DEG is regrown from the first barrier layer 1013 using the P type semiconductor layer 1014 in the gate control region A1 of the first barrier layer 1013 as a mask. Accordingly, problems attributable to etch damage occurring in an existing heterojunction transistor having a gate recess structure using an etch process can be removed, and a high reliable and normally-off heterojunction transistor having a high drain current characteristic can be implemented by the P type semiconductor layer 1014.

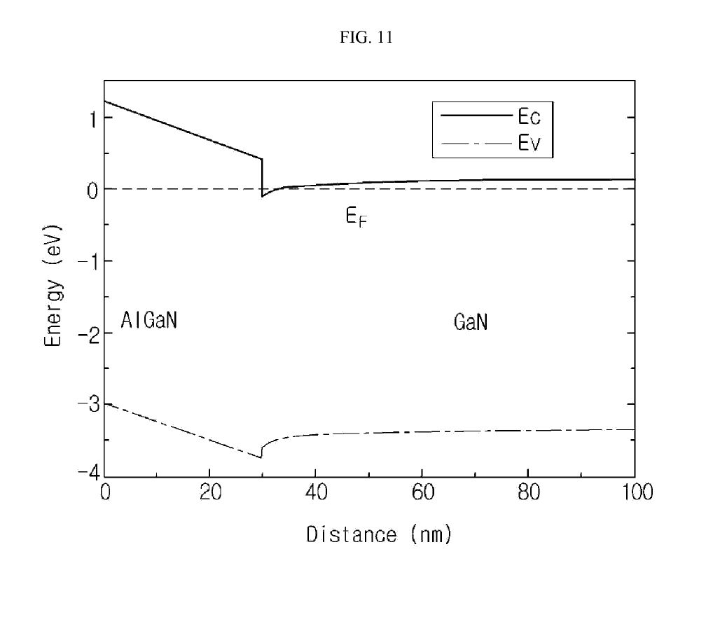

FIG. 11 is an exemplary diagram showing a relationship between the distance and energy of semiconductor layers that are subject to heterojunction in the heterojunction transistor of FIG. 9.

FIG. 11 shows a relationship between the distance extended along line A-A in the heterojunction transistor of FIG. 9 and energy of the heterojunction semiconductor layers.

As shown in FIG. 11, if the channel layer 1012 made of a GaN semiconductor and the barrier layer made of an AlGaN semiconductor are subject to heterojunction, a high-concentration 2DEG channel attributable to a polarization effect is formed in a conduction band edge part due to a difference between energy bandgaps at the interface of a conduction band Ec and a valence band Ev between the two semiconductor materials. Such 2DEG can have an excellent electron transport characteristic in the active region of a semiconductor device, such as a transistor, because the 2DEG is placed in an energy level lower than a Fermi energy level E_{F}.

As described above, the 2DEG is used. Furthermore, in order to effectively implement a normally off heterojunction transistor using a 2DEG channel, in the heterojunction transistor 1010 according to the present exemplary embodiment, the P type semiconductor layer 1014 grown in the gate control region of the thin first barrier layer 1013 and the regrowth barrier layer structure in which the second barrier layer 1015 is formed using the P type semiconductor layer 1014 as a mask are used. That is, the heterojunction transistor 1010 according to the present exemplary embodiment has an excellent normally off characteristic by effectively forming the discontinuous region in the 2DEG channel using the gate recess structure according to the structure of the P type semiconductor layer 1014 under the gate electrode 1016 and the regrowth barrier layer.

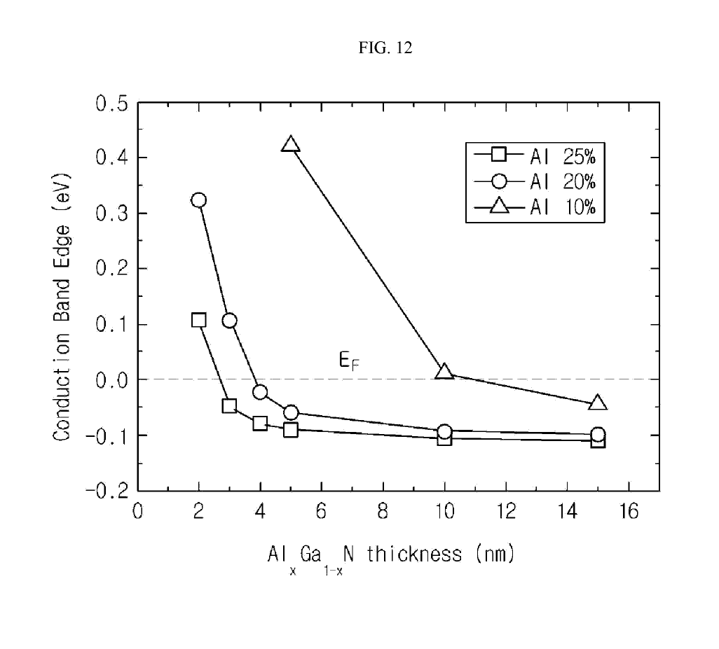

FIG. 12 is an exemplary diagram showing a relationship between the thickness of the barrier layer and a conduction band edge according to an Al composition ratio of the heterojunction transistor of FIG. 9.

As shown in FIG. 12, in an AlₓGa₁₋ₓN barrier layer that forms the first barrier layer 1013 and the second barrier layer 1015, the position of a conduction band edge is may be different depending on an Al composition ratio and a thickness.

That is, when forming the barrier layer to a small thickness, an electron concentration of 2DEG can be increased by raising an Al composition ratio because the electron concentration can be reduced. Furthermore, when it is difficult to form the barrier layer to a small thickness, there may be free from a limit to the thickness because the barrier layer having a low Al composition ratio is formed.

In the present exemplary embodiment, the barrier layer grown to have the heterojunction structure along with the channel layer is divided into at least two layers and regrown, and the P type semiconductor layer 1014 disposed under the gate electrode 1016 is used to regrown the barrier layer. Accordingly, a normally off type heterojunction transistor in which a gate recess structure is efficiently formed without an etch process and a discontinuous region is reliably formed in a 2DEG channel according to heterojunction can be implemented.

In a process of dividing the barrier layer into the first barrier layer 1013 and the second barrier layer 1015 and regrowing the first barrier layer 1013 and the second barrier layer 1015, an electron concentration may be decreased if the thickness of the barrier layer becomes thin, and an electron concentration may be increased if the thickness of the barrier layer becomes thick, but a crack may be generated in the barrier layer due to lattice stress. For example, at an Al concentration of about 25% or more, a crack attributable to lattice stress may be generated before relaxation occurs when the thickness of the barrier layer is increased. Accordingly, there is a need for preferred conditions for forming the aforementioned 2DEG channel and the gate recess structure. Exemplary conditions according to the present exemplary embodiment are described below.

First, if an Al composition ratio is x=0.25 (Al 25%) in a barrier layer made of an AlₓGa₁₋ₓN nitride-based semiconductor, when the thickness of the barrier layer exceeds about 3 nm, a conduction band edge is placed in an energy level lower than a Fermi energy level E_{F}. Accordingly, there may be a difficulty in process control or the formation of a uniform barrier layer when forming the barrier layer into the first barrier layer 1013 and the second barrier layer 1015 regrown from the first barrier layer 1013. That is, if the Al composition ratio of the AlₓGa₁₋ₓN barrier layer is set in the range of 25% to 100%, a critical thickness is exceeded and a 2DEG channel characteristic may be significantly deteriorated because a crack is generated.

Furthermore, in the case of the second barrier layer, if ‘x’ in AlₓGa₁₋ₓN regrown from the first barrier layer 1013 becomes 1, a gallium (Ga) composition ratio becomes 0, and thus the second barrier layer becomes an AlN layer. In such a case, the second barrier layer 1015 made of AlN may have a thickness of about 5 nm or less by taking the critical thickness of the AlN layer into consideration. This is because if the thickness of the AlN layer exceeds 5 nm, a crack may be generated in the AlN layer. Furthermore, if the second barrier layer 1015 is formed of a thin layer, a problem in which positive charges are accumulated on a surface may be generated, and process control may be relatively difficult.

The first barrier layer grown 1013 from the GaN channel layer 1012 have an Al composition ratio of less than 25% by taking a relationship between the aforementioned Al composition ratio and the thickness of the barrier layer into consideration. Furthermore, the Al composition ratio of the first barrier layer 1013 may be about 5% or more by taking the ease of process control and lattice stress attributable to an increase of the thickness into consideration in an Al composition ratio of less than 25%.

When the Al composition ratio (i.e., in a range of about 5% to 25%) is taken into consideration, the thickness of the first barrier layer 1013 may be about 3 nm to about 15 nm.

Furthermore, the Al composition ratio and thickness of the second barrier layer 1015 may be determined depending on the Al composition ratio and thickness of the first barrier layer 1013. The second barrier layer 1015 may have an Al composition ratio of about 15% to 100% and a thickness of about 5 nm to about 30 nm. In the second barrier layer 1015 made of a nitride-based semiconductor, if the thickness of the second barrier layer 1015 is about 5 nm, channel resistance may be increased because an electron concentration of 2DEG is low. If the thickness of the second barrier layer 1015 exceeds 30 nm, a crack may be generated due to lattice stress and a lot of time may be taken for a process of forming the second barrier layer 1015.

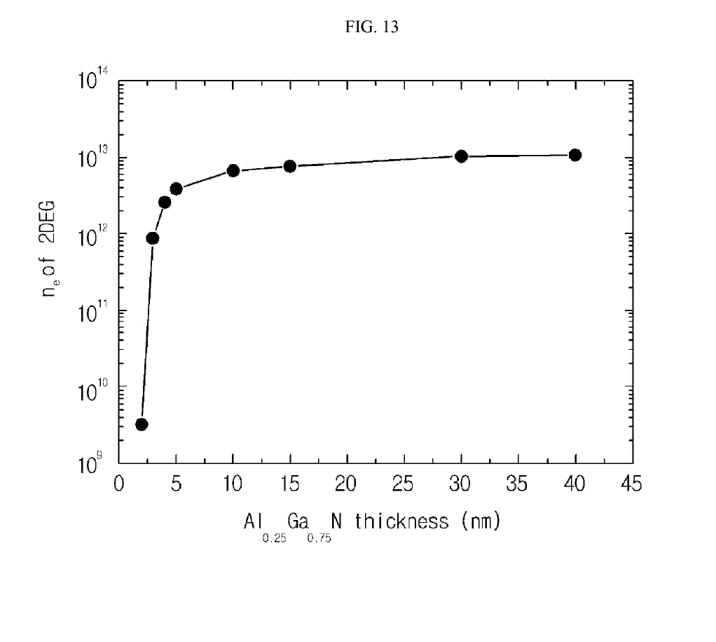

FIG. 13 is an exemplary diagram showing a relationship between the thickness of the barrier layer 1012 of the heterojunction transistor 1010 shown in FIG. 9 and the electron density of 2DEG.

As shown in FIG. 13, if the thickness of the barrier layer made of an AlₓGa₁₋ₓN nitride-based semiconductor becomes thin, the electron density nₑ of the 2DEG channel may be suddenly decreased in a specific thickness or less (e.g., about 3˜5 nm). That is, if the thickness of the AlGaN barrier layer having a specific aluminum (Al) concentration (e.g., 25%) is smaller than the specific thickness, a discontinuous region in which the 2DEG channel is not formed may be formed because spontaneous polarization and a piezoelectric effect are reduced in the 2DEG channel.

By taking a possible formation of the discontinuous region into consideration, in the regrowth barrier layer structure of the present exemplary embodiment, first, the thickness of the first barrier layer 1013 from the channel layer 1012 is formed in a thickness in which the 2DEG channel has not been formed when the first barrier layer 1013 is subject to heterojunction with the channel layer 1012. Thereafter, the second barrier layer 1015 regrown in the gate non-control regions of the first barrier layer 1013 is formed in a thickness in which the 2DEG channel has been formed when the channel layer 1012 is subject to heterojunction with the barrier layer (i.e., the first and the second barrier layers 1013 and 1015). Moreover, when growing the second barrier layer 1015 from the first barrier layer 1013 in a selective region, the P type semiconductor layer 1014 grown from the first barrier layer 1013 and placed under the gate electrode 1016 is used. Accordingly, the present exemplary embodiment can provide the heterojunction transistor having an excellent normally off characteristic through the recess p-GaN gate structure of the second barrier layer 1015 that is grown from the thin first barrier layer 1013 using the P type semiconductor layer 1014 under the gate electrode 1016 as a mask.

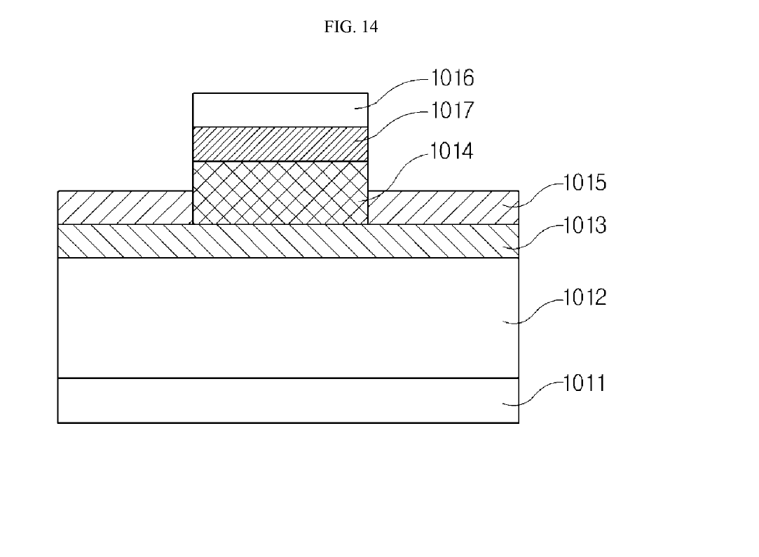

FIG. 14 is a cross-sectional view of a heterojunction transistor in accordance with an exemplary embodiment of the present invention.

Referring to FIG. 14, the heterojunction transistor has a Metal Insulator Semiconductor (MIS)-Heterojunction Field Effect Transistor (HFET) structure and includes the substrate 1011, the channel layer 1012, the first barrier layer 1013, the P type semiconductor layer 1014, the second barrier layer 1015, and the gate electrode 1016. The heterojunction transistor has a recess p-GaN gate structure including the second barrier layer 1015 that is regrown from the first barrier layer 1013 using the P type semiconductor layer 1014 under the gate electrode 1016 as a mask. Accordingly, a gate recess structure can be formed in the gate control region without an etch process, and problems occurring in an etch process can be prevented and an excellent normally off characteristic can be implemented because the P type semiconductor layer 1014 is disposed under the gate electrode 1016.

The heterojunction transistor according to the present exemplary embodiment is substantially the same as the heterojunction transistor described with reference to FIG. 3 except that the insulating masking layer 1017 capable of functioning as a gate insulating film is disposed in the recess p-GaN gate structure, and a redundant description thereof is omitted.

The insulating masking layer 1017 may be implemented by controlling subsequent processes such that the insulating film placed over the P type semiconductor 1014 is not removed when forming the second barrier layer 1015 in the heterojunction transistor fabricated using the method described with reference to FIGS. 10A to 10D. If a case where a manufacturing process becomes more complicated is not taken into consideration, however, the insulating masking layer 1017 may be formed into a gate insulating film using additional insulating materials after being removed as in the method described with reference to FIGS. 10A to 10D.

The heterojunction transistor according to the present exemplary embodiment shows a high threshold voltage characteristic and a low gate leakage characteristic by way of the insulating masking layer 1017 placed between the gate electrode 1016 and the channel layer 1013 and configured to function as a gate insulating film and a manufacturing process can be simplified because a process of removing the insulating masking layer is omitted, as compared with the heterojunction transistor of FIG. 9.

In accordance with the aforementioned exemplary embodiments, the first barrier layer 1013 subject to heterojunction with the channel layer 1012 is thinly formed, and the second barrier layer 1015 is selectively regrown on the first barrier layer 1013 using the P type semiconductor layer 1014 grown from the first barrier layer 1013 as a mask. Accordingly, the heterojunction transistor having a new recess p-GaN gate structure with an excellent normally off characteristic can be implemented, the flexibility of a process can be improved because there is no limit to a composition ratio and thickness of the barrier layer, and reappearance can be improved because device characteristics become more uniform.

As described above, the heterojunction transistor and the method of fabricating the same according to exemplary embodiments of the present invention disclose that the thickness of the barrier layer under the gate electrode can be thinly controlled through the regrowth scheme without an etch process and thus a gate leakage problem attributable to plasma damage to a surface under the gate electrode and a problem in that reliability of a device is deteriorated can be prevented.

The heterojunction transistor and a method of fabricating the same in accordance with an exemplary embodiment of the present invention disclose that the Al composition ratio and thickness of the switching control region can be easily controlled by an epitaxial process when growing a primary barrier layer and thus a change of device characteristics attributable to an etch process can be prevented because a process of etching the barrier layer in the switching control region is omitted.

The heterojunction transistor and the method of fabricating the same in accordance with an exemplary embodiment of the present invention disclose that the Al composition ratio and thickness of the barrier layer in the switching non-control regions can be easily controlled by a plurality of growth processes and thus device characteristics including the electron density of the 2DEG channel can be easily controlled.

The heterojunction transistor and the method of fabricating the same in accordance with an exemplary embodiment of the present invention have an advantage in that a method of fabricating a transistor can be simplified because the insulating masking layer formed in the switching control region is used as a gate electrode insulating film when growing a secondary barrier layer.

The heterojunction transistor and the method of fabricating the same in accordance with an exemplary embodiment of the present invention discloses that a drain current characteristic can be improved as compared with an existing MIS-HFET structure.

The heterojunction transistor and the method of fabricating the same in accordance with an exemplary embodiment of the present invention discloses that an interfacial characteristic between the gate electrode and the channel layer can be improved.

The heterojunction transistor and the method of fabricating the same in accordance with an exemplary embodiment of the present invention discloses that a threshold voltage can be improved because a combination of the P type semiconductor layer and the insulating masking layer is used.

While the present invention has been described with respect to the specific embodiments, it will be apparent to those skilled in the art that various changes and modifications may be made without departing from the spirit and scope of the invention as defined in the following claims.

What is claimed is:

1. A method of fabricating a heterojunction transistor, the method comprising:
forming a channel layer on a substrate, the channel layer comprising a first nitride-based semiconductor having a first energy bandgap;
forming a first barrier layer on the channel layer, the first barrier layer comprising a second nitride-based semiconductor having a second energy bandgap different from the first energy bandgap;
forming an insulating masking layer to a first thickness in a gate control region on the first barrier layer;
forming a second barrier layer on the first barrier layer, the second barrier layer comprising a third nitride-based semiconductor having a third energy bandgap different from the first energy bandgap, the second barrier layer formed to a second thickness identical with or less than the first thickness of the insulating masking layer; and
removing the insulating masking layer and forming a gate electrode on the first barrier layer in the gate control region.

2. The method of claim 1, wherein:
the first barrier layer is formed to a third thickness of about 3 nm to about 15 nm, in which a Two-Dimensional Electron Gas (2DEG) channel is not formed through a junction of the channel layer and the first barrier layer in a state in which a bias has not been applied to the gate electrode; and
the second barrier layer is formed to the second thickness of about 5 nm to about 30 nm, in which the 2DEG channel is formed through a junction of the first barrier layer, the second barrier layer, and the channel layer in a state in which a bias has not been applied to the gate electrode.

3. The method of claim 2, wherein:
the second energy bandgap is greater than the first energy bandgap; and
the third energy bandgap is greater than the first energy bandgap.

4. The method according to claim 3, wherein:
the second thickness is greater than the third thickness; and
the third energy bandgap is the same as the second energy bandgap.

5. The method of claim 1, wherein forming the insulating masking layer comprises:
forming an insulating layer on the first barrier layer;
forming a patterned photoresist layer on the insulating layer;
removing the insulating layer on gate non-control regions other than the gate control region; and
forming the insulating masking layer by removing the photoresist layer.

6. A method of fabricating a heterojunction transistor, the method comprising:
forming a channel layer on a substrate, the channel layer comprising a first nitride-based semiconductor having a first energy bandgap;
forming a first barrier layer on the channel layer, the first barrier layer comprising a second nitride-based semiconductor having a second energy bandgap different from the first energy bandgap;
forming an insulating masking layer to a first thickness in a gate control region on the first barrier layer;
forming a second barrier layer on the first barrier layer, the second barrier layer comprising a third nitride-based semiconductor having a third energy bandgap different from the first energy bandgap, the second barrier layer formed to a second a thickness identical with or less than the first thickness of the insulating masking layer; and
forming a gate electrode on the insulating masking layer.

7. The method of claim 6, wherein the forming the gate electrode comprises forming the gate electrode on the insulating masking layer that remains after removing part of the insulating masking layer.

8. The method of claim 6, wherein:
the first barrier layer is formed to a third thickness of about 3 nm to about 15 nm, in which a Two-Dimensional Electron Gas (2DEG) channel is not formed through a junction of the channel layer and the first barrier layer in a state in which a bias has not been applied to the gate electrode; and
the second barrier layer is formed to a second thickness of about 5 nm to about 30 nm, in which the 2DEG channel is formed through a junction of the first barrier layer, the second barrier layer, and the channel layer in a state in which a bias has not been applied to the gate electrode.

9. The method according to claim 8, wherein:
the second energy bandgap is greater than the first energy bandgap; and
the third energy bandgap is greater than the first energy bandgap.

10. A heterojunction transistor, comprising:
a substrate;
a channel layer disposed on the substrate, the channel layer comprising a first nitride-based semiconductor having a first energy bandgap;
a first barrier layer disposed on the channel layer, the first barrier layer comprising a second nitride-based semiconductor having a second energy bandgap different from the first energy bandgap;
a gate electrode disposed in a gate control region of the first barrier layer;
a second barrier layer disposed in gate non-control regions of the first barrier layer separately from the first barrier layer; and
a source electrode and a drain electrode disposed on the second barrier layer.

11. The heterojunction transistor of claim 10, wherein the gate electrode is disposed in the gate control region of the first barrier layer, and the insulating masking layer is interposed between the gate electrode and the first barrier layer.

12. The heterojunction transistor of claim 11, wherein:
the first barrier layer comprises a first thickness of about 3 nm to 15 nm, in which a Two-Dimensional Electron Gas (2DEG) channel is configured to not be formed through a junction of the channel layer and the first barrier layer in a state in which a bias has not been applied to the gate electrode; and
the second barrier layer comprises a second thickness of about 5 nm to about 30 nm, in which the 2DEG channel is configured to be formed through a junction of the first barrier layer, the second barrier layer, and the channel layer in a state in which a bias has not been applied to the gate electrode.

13. The heterojunction transistor of claim 10, wherein:
the second energy bandgap is greater than the first energy bandgap; and
the third energy bandgap is greater than the first energy bandgap.

14. A method of fabricating a heterojunction transistor, the method comprising:
forming a channel layer on a substrate, the channel layer comprising a first nitride-based semiconductor having a first energy bandgap;
forming a first barrier layer on the channel layer, the first barrier layer comprising a second nitride-based semiconductor having a second energy bandgap different from the first energy bandgap;
forming a P type semiconductor layer in a gate control region on the first barrier layer;
forming a second barrier layer on the first barrier layer, the second barrier layer comprising a third nitride-based semiconductor having a third energy bandgap different from the first energy bandgap, the second barrier layer formed to a second thickness identical with or less than a first thickness of the P type semiconductor layer; and
forming a gate electrode on the P type semiconductor layer.

15. The method of claim 14, wherein:
the first barrier layer is formed to a third thickness of about 3 nm to about 15 nm, in which a Two-Dimensional Electron Gas (2DEG) channel is not formed through a junction of the channel layer and the first barrier layer in a state in which a bias has not been applied to the gate electrode; and
the second barrier layer is formed to the second thickness of about 5 nm to about 30 nm, in which the 2DEG channel is formed through a junction of the first barrier layer, the second barrier layer, and the channel layer in a state in which a bias has not been applied to the gate electrode.

16. The method of claim 15, wherein:
the second energy bandgap is greater than the first energy bandgap; and
the third energy bandgap is greater than the first energy bandgap.

17. The method of claim 14, wherein forming the P type semiconductor layer comprises:
forming the P type semiconductor layer on an entire surface of the first barrier layer by growing the first barrier layer; and
patterning the P type semiconductor layer to be disposed in the gate control region by etching the P type semiconductor layer formed on the entire surface of the first barrier layer.

18. A method of fabricating a heterojunction transistor, the method comprising:
forming a channel layer on a substrate, the channel layer comprising a first nitride-based semiconductor having a first energy bandgap;
forming a first barrier layer on the channel layer, the first barrier layer comprising a second nitride-based semiconductor having a second energy bandgap different from the first energy bandgap;
forming a P type semiconductor layer in a gate control region on the first barrier layer;
forming a second barrier layer on the first barrier layer, the second barrier layer comprising a third nitride-based semiconductor having a third energy bandgap different from the first energy bandgap, the second barrier layer formed to a thickness equal to or less than a thickness of the P type semiconductor layer using an insulating masking layer patterned to cover the P type semiconductor layer; and
forming a gate electrode on the insulating masking layer.

19. The method according to claim 18, wherein:
the first barrier layer is formed to a thickness of about 3 nm to about 15 nm, in which a Two-Dimensional Electron Gas (2DEG) channel is not formed through a junction of the channel layer and the first barrier layer in a state in which a bias has not been applied to the gate electrode; and
the second barrier layer is formed to a thickness of about 5 nm to about 30 nm, in which the 2DEG channel is formed through a junction of the first barrier layer, the second barrier layer, and the channel layer in a state in which a bias has not been applied to the gate electrode.

20. The method according to claim 19, wherein:
the second energy bandgap is greater than the first energy bandgap; and
the third energy bandgap is greater than the first energy bandgap.

21. The method according to claim 20, wherein:
the second barrier layer is formed to a thickness greater than a thickness of the first barrier layer; and
the second barrier layer comprises the third nitride-based semiconductor having the third energy bandgap identical with the second energy bandgap.

22. The method according to claim 18, wherein forming the P type semiconductor layer comprises:
forming the P type semiconductor layer on an entire surface of the first barrier layer by growing the first barrier layer; and
forming the P type semiconductor layer patterned to be positioned in the gate control region by etching the P type semiconductor layer formed on the entire surface of the first barrier layer.

23. A heterojunction transistor, comprising:
a substrate;
a channel layer disposed on the substrate, the channel layer comprising a first nitride-based semiconductor having a first energy bandgap;
a first barrier layer disposed on the channel layer, the first barrier layer comprising a second nitride-based semiconductor having a second energy bandgap different from the first energy bandgap;
a P type semiconductor layer disposed in a gate control region of the first barrier layer;
a second barrier layer disposed on the first barrier layer at a thickness equal to or lower than of a thickness of the P type semiconductor layer;
a gate electrode disposed on the P type semiconductor layer; and
a source electrode and a drain electrode disposed on the second barrier layer.

24. The heterojunction transistor according to claim 23, wherein:
the first barrier layer or the second barrier layer is doped with n type impurities;
the first barrier layer comprises a thickness of about 3 nm to about 15 nm, in which a Two-Dimensional Electron Gas (2DEG) channel is not formed through a junction of the channel layer and the first barrier layer in a state in which a bias has not been applied to the gate electrode; and
the second barrier layer comprises a thickness of about 5 nm to about 30 nm, in which the 2DEG channel is formed through a junction of the first barrier layer, the second barrier layer, and the channel layer in a state in which a bias has not been applied to the gate electrode.

25. The heterojunction transistor according to claim 23, wherein:
the second energy bandgap is greater than the first energy bandgap; and
the third energy bandgap is greater than the first energy bandgap.

26. The heterojunction transistor according to claim 23, further comprising:
a buffer layer disposed on the substrate;
a high-temperature undoped GaN layer disposed on the buffer layer; and
a compensation layer disposed on the high-temperature undoped GaN layer, the compensation layer comprising a GaN semiconductor doped with electron-trapping impurities,
wherein the channel layer is disposed on the compensation layer, and of the channel layer comprises a GaN semiconductor having a defect density of 5E8/cm² or less.
